(19) United States
(12) Patent Application Publication
(10) Pub. No.: US 2026/0181992 A1
(43) Pub. Date: Jun. 25, 2026

(54) SEMICONDUCTOR DEVICES WITH ASYMMETRIC FIELD RELIEF LAYERS AND METHODS OF FABRICATION THEREOF

(71) Applicant: TEXAS INSTRUMENTS INCORPORATED, Dallas, TX (US)

(72) Inventor: Alexei Sadovnikov, Sunnyvale, CA (US)

(21) Appl. No.: 19/000,904

(22) Filed: Dec. 24, 2024

(51) Int. Cl. H10D 64/27; H01L 21/28; H10D 30/01; H10D 30/65; H10D 64/01

(52) U.S. Cl. CPC H10D 64/516; H10D 30/0281; H10D 30/65; H10D 64/01336; H10D 64/01

(57) ABSTRACT

Semiconductor devices and fabrication methods thereof are described. For example, a semiconductor device includes a semiconductor layer, a drain region disposed in the semiconductor layer, a source region disposed in the semiconductor layer, and a gate stack disposed between the drain region and the source region. The semiconductor device also includes an asymmetric field relief layer disposed at least partially in the semiconductor layer between the drain region and the source region, the asymmetric field relief layer having a first end with a first profile and a second end with a second profile different than the first profile.

### TECHNICAL FIELD

The present disclosure relates to the field of semiconductor devices, and more particularly, but not exclusively, to laterally diffused metal oxide semiconductor (LDMOS) transistors.

### BACKGROUND

LDMOS devices are field-effect transistors (FETs) that are utilized in high power applications. In an LDMOS device, the drain and source have a relatively large spacing between them, as compared with MOS devices for other applications, and lateral diffusions are used to produce a well-controlled channel region under the gate. The operational performance of LDMOS devices is generally affected by parameters including, for example, a specific on-resistance (Rsp) and a breakdown voltage (BV). A desirable approach for LDMOS devices is to decrease Rsp and increase BV, or at least to improve one parameter without adversely affecting the other parameter in a significant manner.

### SUMMARY

The present disclosure describes semiconductor devices with asymmetric field relief layers and methods of fabrication thereof. This summary is not an extensive overview of the disclosure. Rather, a purpose of the summary is to present some examples of the present disclosure in a simplified form as a prelude to a more detailed description that is presented later.

In one example, a semiconductor device includes a semiconductor layer, a drain region disposed in the semiconductor layer, a source region disposed in the semiconductor layer, and a gate stack disposed between the drain region and the source region. The semiconductor device also includes an asymmetric field relief layer disposed at least partially in the semiconductor layer between the drain region and the source region, the asymmetric field relief layer having a first end with a first profile and a second end with a second profile different than the first profile.

In another example, a semiconductor device includes a semiconductor layer, a drain region disposed in the semiconductor layer, a source region disposed in the semiconductor layer, and a gate stack disposed between the drain region and the source region. The semiconductor device also includes a field relief layer disposed between the drain region and the source region, and at least partially in the semiconductor layer, the field relief layer having a first end adjacent to the drain region with a first profile and a second end adjacent to the source region with a second profile, wherein the first profile is smaller in width, defined in a direction along a surface of the semiconductor layer, relative to the second profile.

In an additional example, a method of fabricating a semiconductor device includes forming an asymmetric field relief layer disposed partially in a semiconductor layer and partially above a surface of the semiconductor layer, the asymmetric field relief layer having a first end with a first profile and a second end with a second profile different than the first profile. The method also includes forming a drain region, a source region, and a gate stack, the drain region being proximate to the first end of the asymmetric field relief layer, the source region being proximate to the second end of the asymmetric field relief layer, and the gate stack being between the drain region and the source region and partially over the asymmetric field relief layer.

### BRIEF DESCRIPTION OF THE DRAWINGS

FIG. 1 is a cross-sectional view of a semiconductor device with an asymmetric field relief layer in accordance with an example of the present disclosure;

FIGS. 2A-2Q are cross-sectional views of a process flow for forming a semiconductor device with an asymmetric field relief layer in accordance with the example of FIG. 1;

FIG. 3 is a cross-sectional view of a semiconductor device with an asymmetric field relief layer in accordance with another example of the present disclosure; and

FIGS. 4A-4R are cross-sectional views of a process flow for forming a semiconductor device with an asymmetric field relief layer in accordance with the example of FIG. 3.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about” or “approximately,” preceding a value mean +/−10-20 percent (%) of the stated value. The terms “substantially” or “substantially equal” means values within ±2.5% of the stated value. Still further, unless otherwise specified, the ordering of steps in the description and in the claims are not intended to limit sequencing of the performance of steps and thus alternate step sequencing is contemplated as appropriate.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

As mentioned, the operational performance of an LDMOS device is generally affected by a tradeoff between a specific on-resistance (Rsp) parameter and a breakdown voltage (BV) parameter. For example, approaches that seek to achieve the advantage of a higher BV by increasing the body area of the device consequently lead to the disadvantage of a higher Rsp. Similarly, approaches that seek to decrease Rsp generally come at the cost of decreasing the BV rating. Accordingly, desirable approaches for LDMOS devices that effectively manage this tradeoff provide technical advantages.

LDMOS devices, and other power devices, may utilize field relief regions for tuning the Rsp and BV parameters. Such field relief regions, which typically include one or more dielectric materials disposed (at least partially) below a gate stack, may take different forms. Examples of field relief regions include: (i) a shallow trench isolation (STI) layer which is a field relief region formed in a trench below a surface of a semiconductor layer of the LDMOS device; (ii) a step gate layer which is a field relief region formed above a surface of the semiconductor layer; and (iii) a local oxidation of silicon (LOCOS) layer which is a field relief region formed at least partially in the semiconductor layer (e.g., partially above and partially below a surface of the semiconductor layer).

While each form of field relief region provides technical advantages, e.g., reducing electric field to improve the BV rating of the device, a LOCOS layer may be regarded as technically advantageous over STI and step gate approaches, for example, by avoiding the relatively sharp dielectric sidewall transitions inherent in STI and step gate layer formations.

In general, a typical process for forming a LOCOS layer involves depositing a relatively thin pad oxide layer (e.g., silicon oxide) on the semiconductor layer (e.g., silicon, silicon substrate) and then depositing a silicon nitride layer on the pad oxide layer. The silicon nitride layer is patterned and etched (along with a portion of the pad oxide) to define an area of the silicon where a LOCOS layer is formed. A relatively high-temperature (e.g., about 700 to about 1200 degrees Celsius (°C.)) thermal oxidation process is then performed causing the area of the silicon to oxidize and form a relatively thick layer of silicon dioxide partially above and partially below the surface of the semiconductor layer. The silicon nitride layer is then removed leaving the silicon dioxide which is referred to as the LOCOS layer.

In addition, a typical LOCOS process forms approximately symmetrical (same or similar) tapered profiles at the boundary (e.g., each end) of the LOCOS layer, referred to as bird's beaks. Such bird's beak profiles provide a relatively smooth transition for the LOCOS layer with respect to a subsequently formed gate dielectric layer under the gate stack. The smoother transition better reduces the electric field and thus more substantially increases the BV of the device, as compared to STI and step gate approaches. In theory, the longer the bird's beak, the more gradual the gate dielectric layer transition, and the better BV improvement. In practice, however, longer bird's beaks can encroach into the silicon area adjacent to the LOCOS layer (e.g., silicon area occupied by the drain region) necessitating expanding the adjacent silicon area—e.g., expanding the drain region so as to ensure sufficient width to adequately silicide the drain region and form a drain contact. However, increasing the drain region increases the half-pitch of the LDMOS device and causes increased Rsp. Moreover, longer bird's beaks can increase the likelihood of “nitride peel”—e.g., the silicon nitride layer prematurely separating from the pad oxide layer during the LOCOS process.

To address the above and other technical challenges in LDMOS and other power devices, examples of the present disclosure describe semiconductor devices with asymmetric field relief layers (e.g., asymmetric LOCOS layers) and methods of fabrication thereof. While examples of the disclosure may be expected to provide improvements such as may be described herein, no particular result is a requirement of the present invention unless explicitly recited in a particular claim.

In one example, a semiconductor device includes a semiconductor layer, drain and source regions disposed in the semiconductor layer, and a gate stack disposed between the drain and source regions. The semiconductor device also includes an asymmetric field relief layer disposed at least partially in the semiconductor layer between the drain region and the source region, the asymmetric field relief layer having a first end with a first profile and a second end with a second profile different than the first profile. In some examples, the first end of the asymmetric field relief layer is adjacent to the drain region and the second end of the asymmetric field relief layer is adjacent to the source region.

In some examples, the first end with the first profile includes a first tapered portion having a first slope, and the second end with the second profile includes a second tapered portion having a second slope less than the first slope.

In some examples, the first end with the first profile includes a first tapered portion having a first width extending in a direction along a surface of the semiconductor layer, and the second end with the second profile includes a second tapered portion having a second width extending in the direction along the surface of the semiconductor layer and greater than the first width.

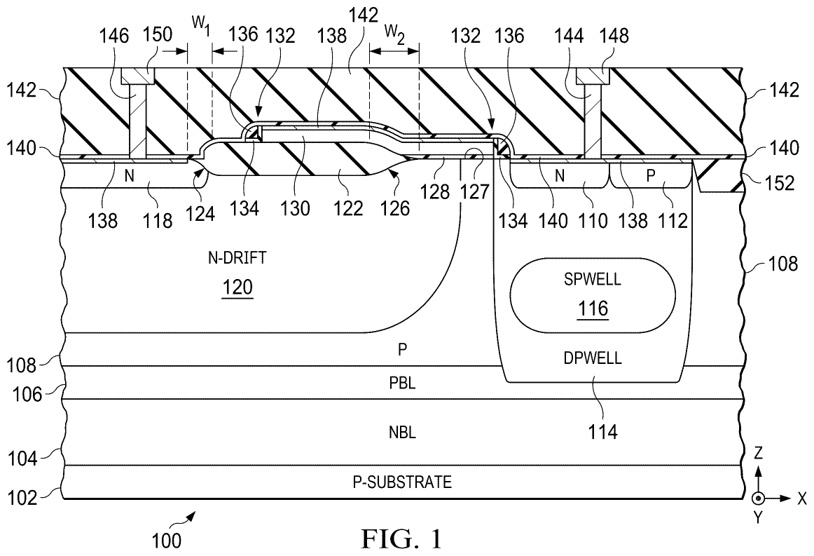

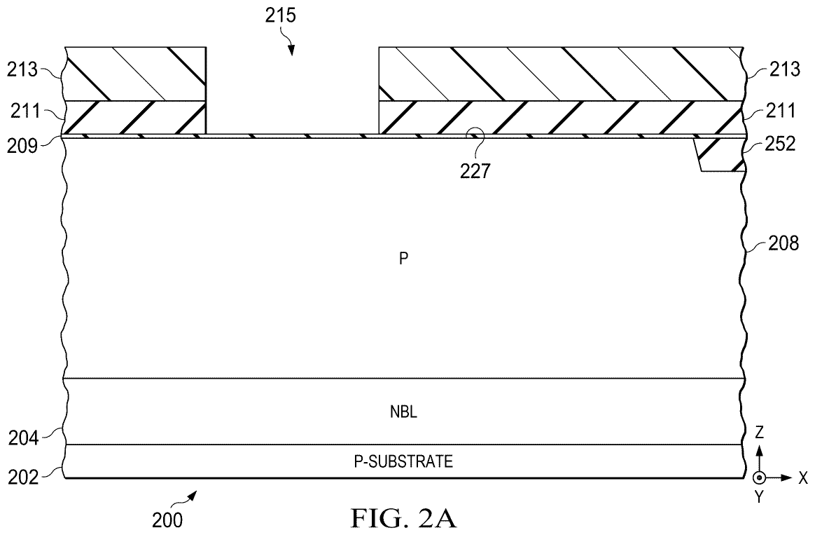

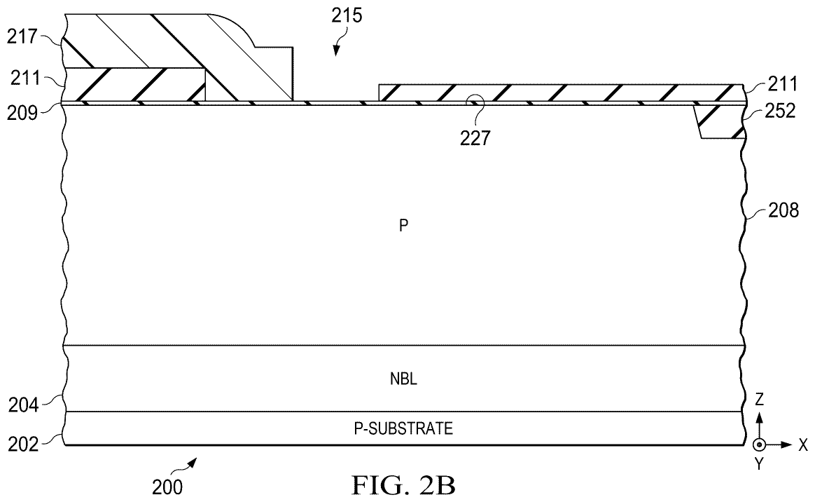

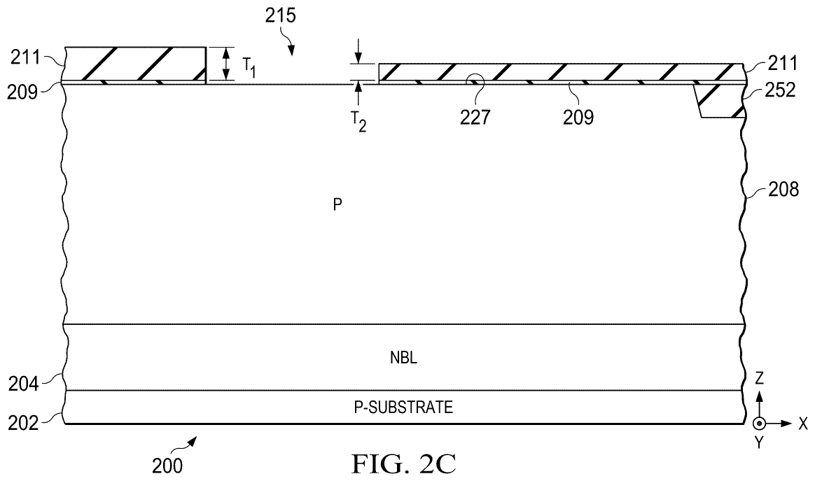

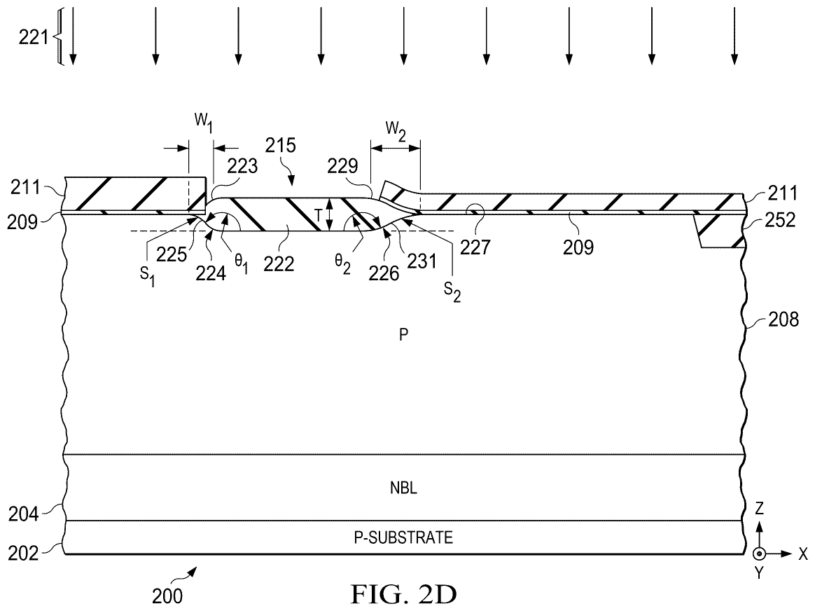

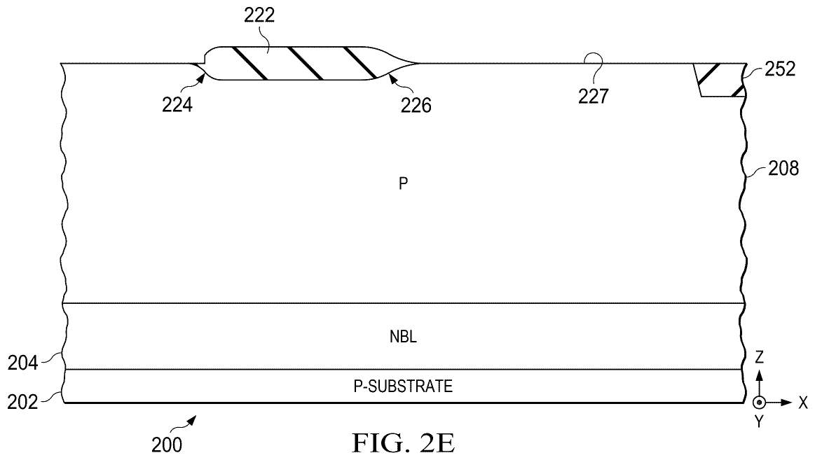

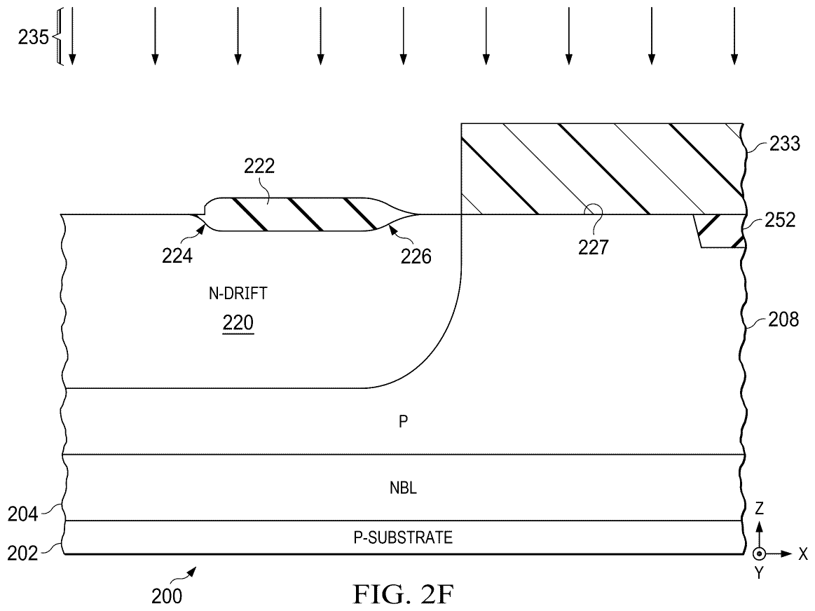

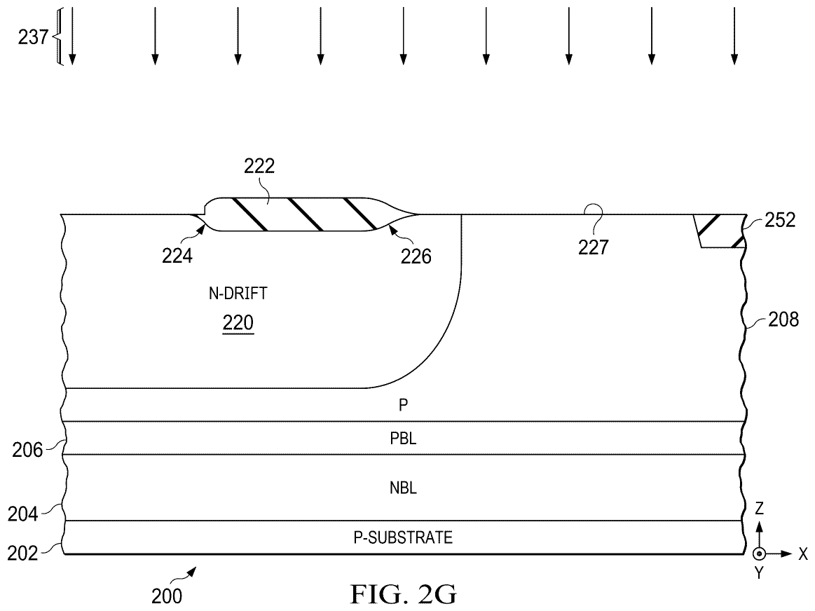

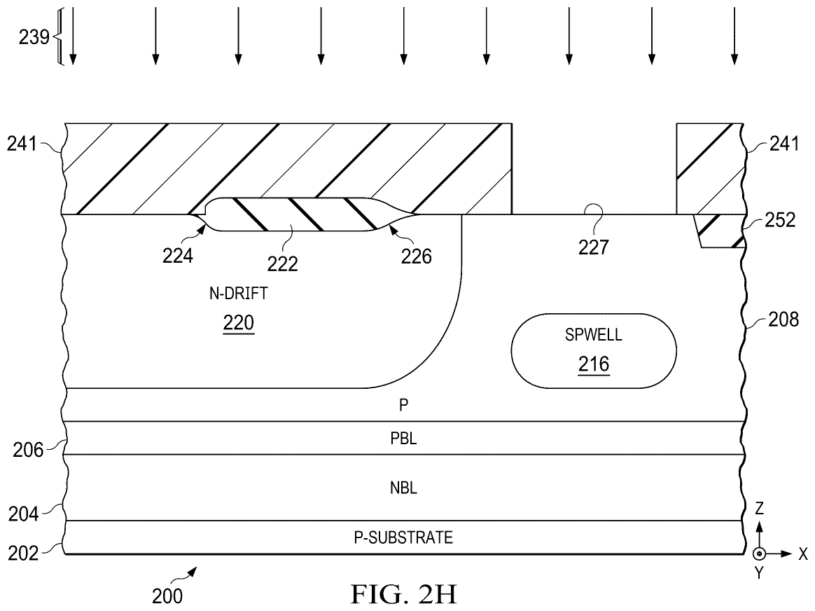

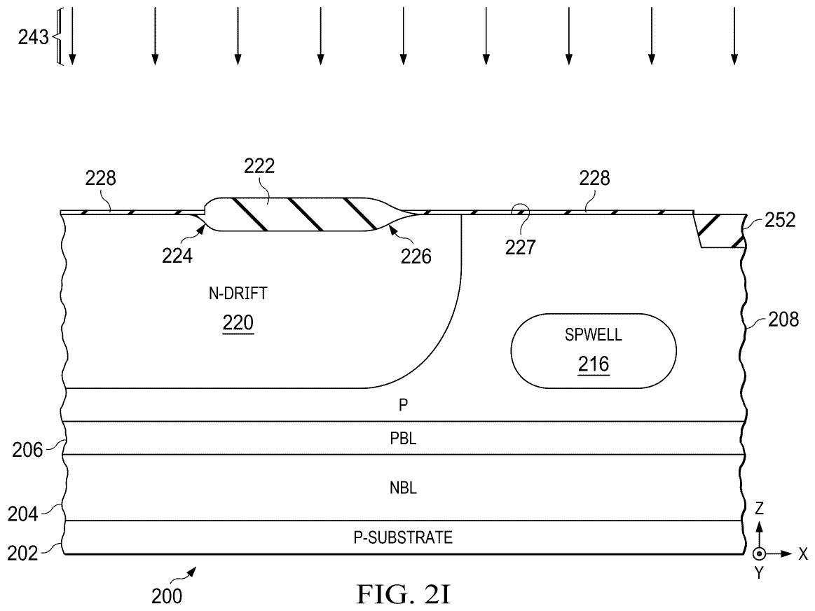

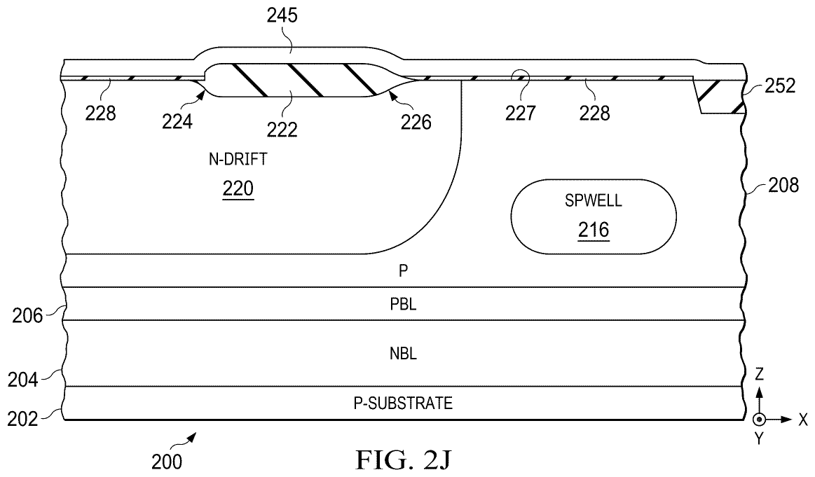

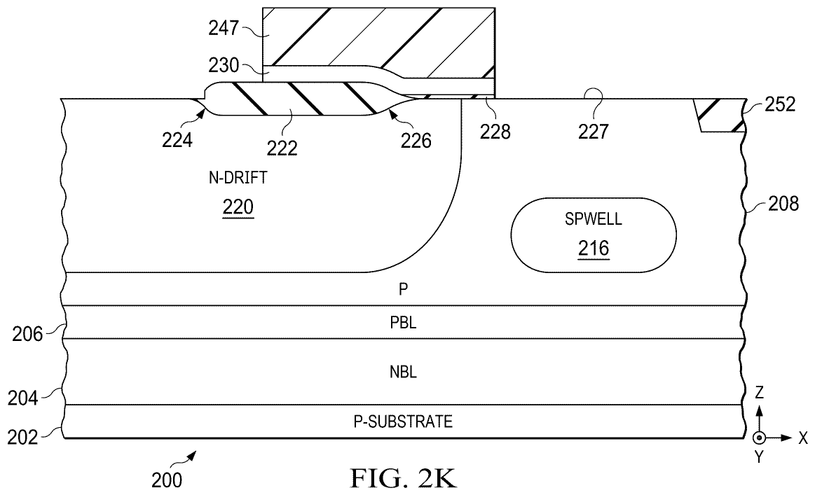

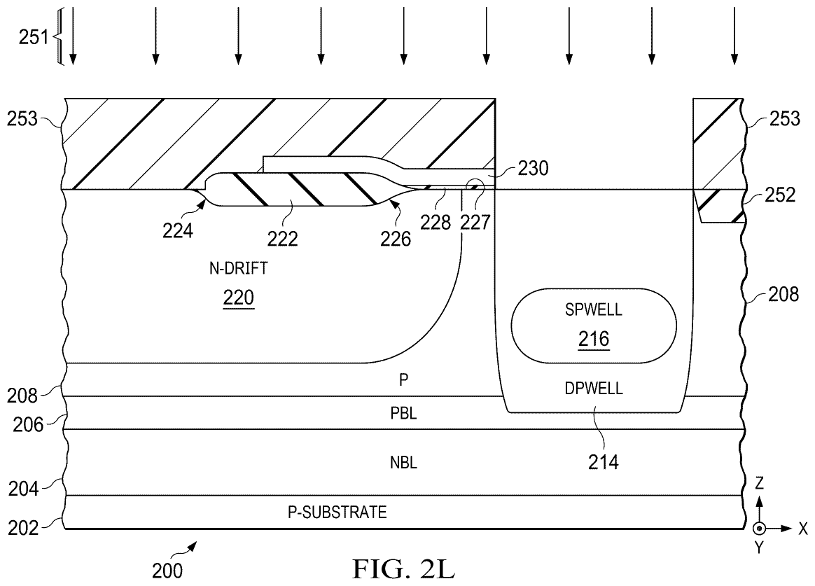

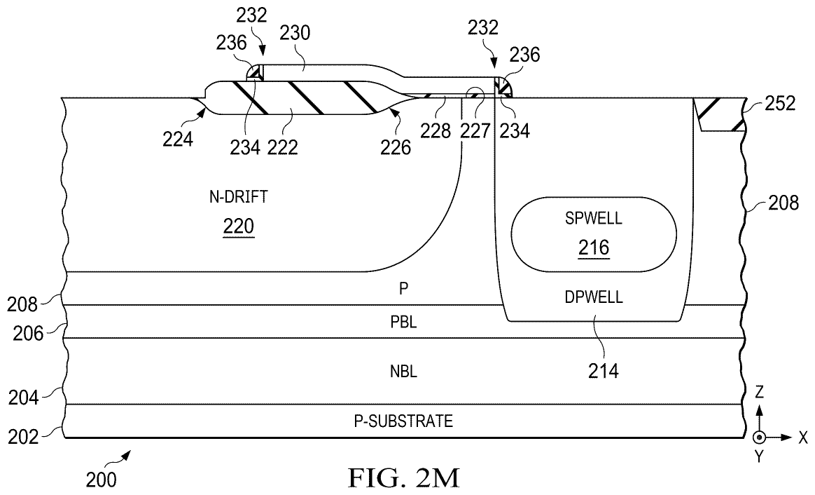

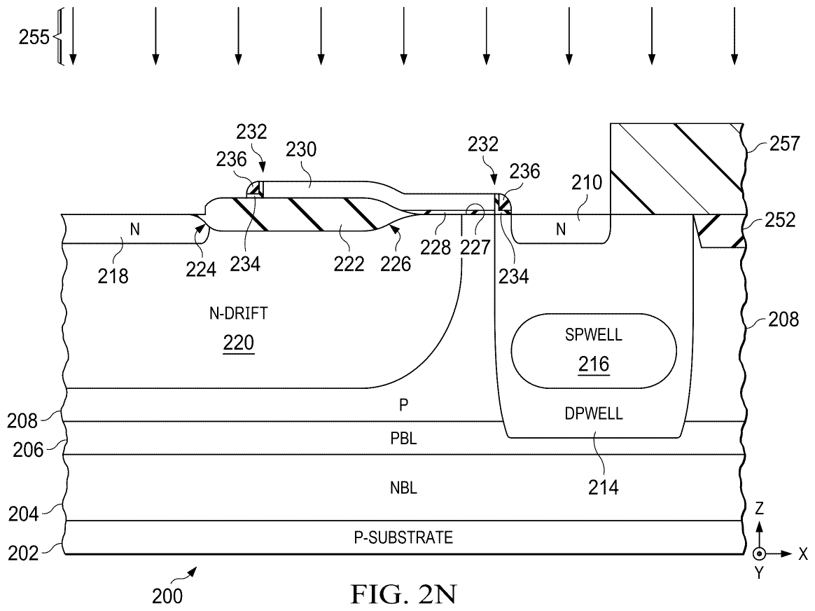

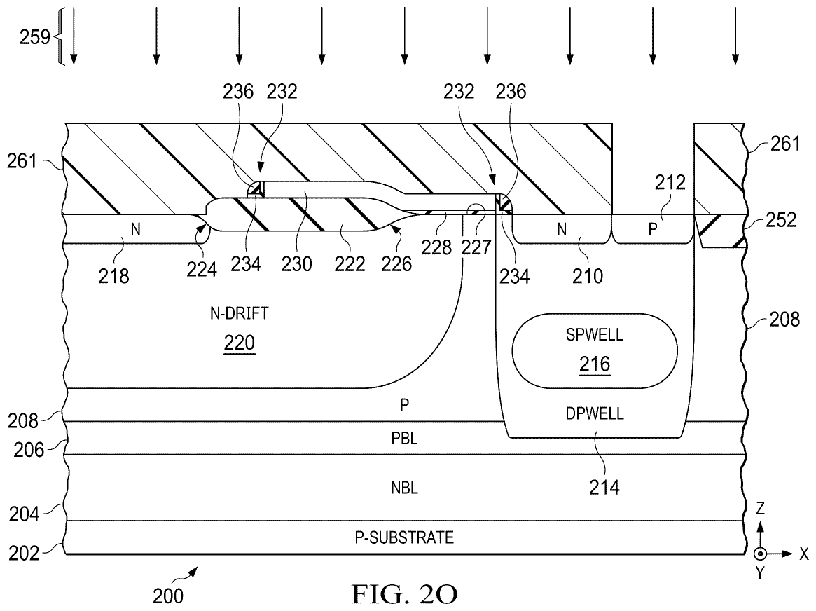

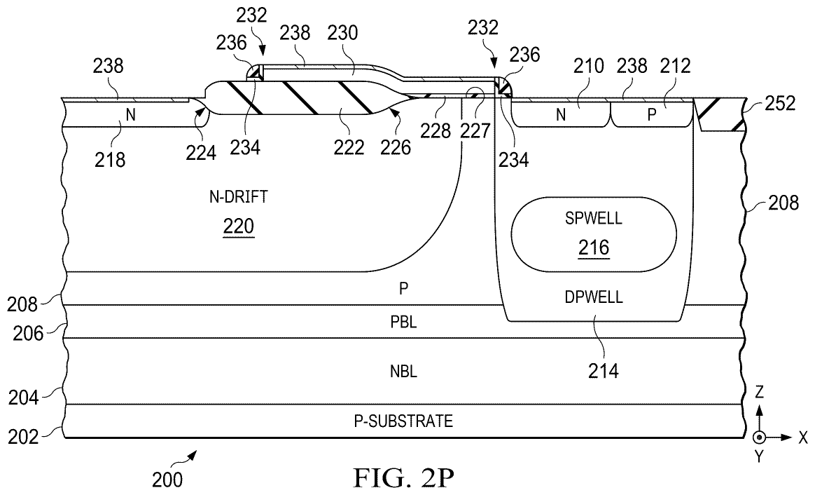

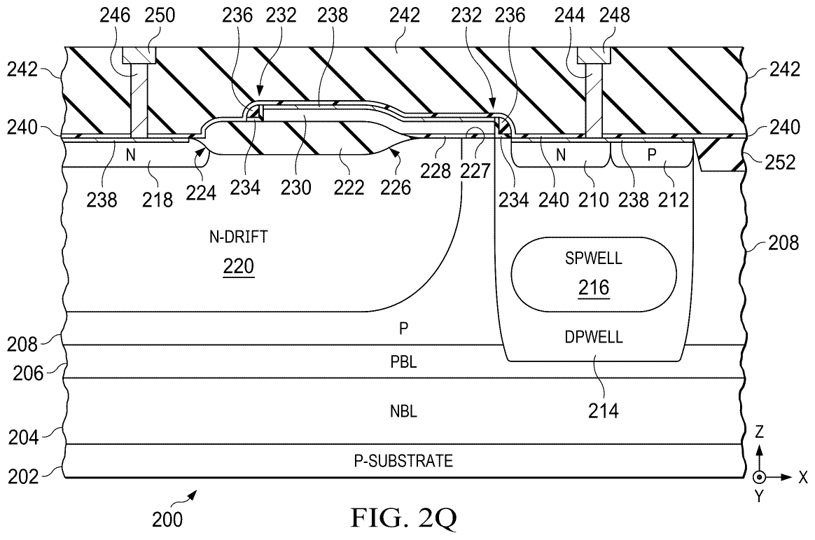

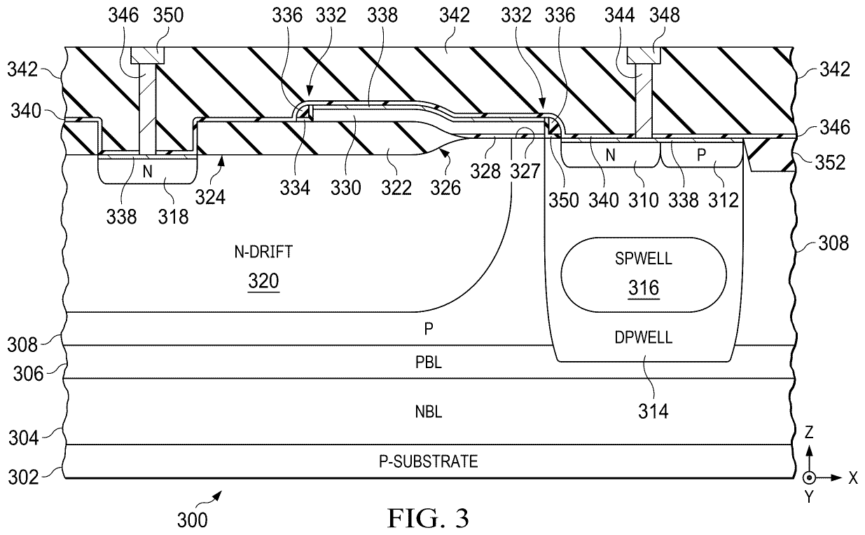

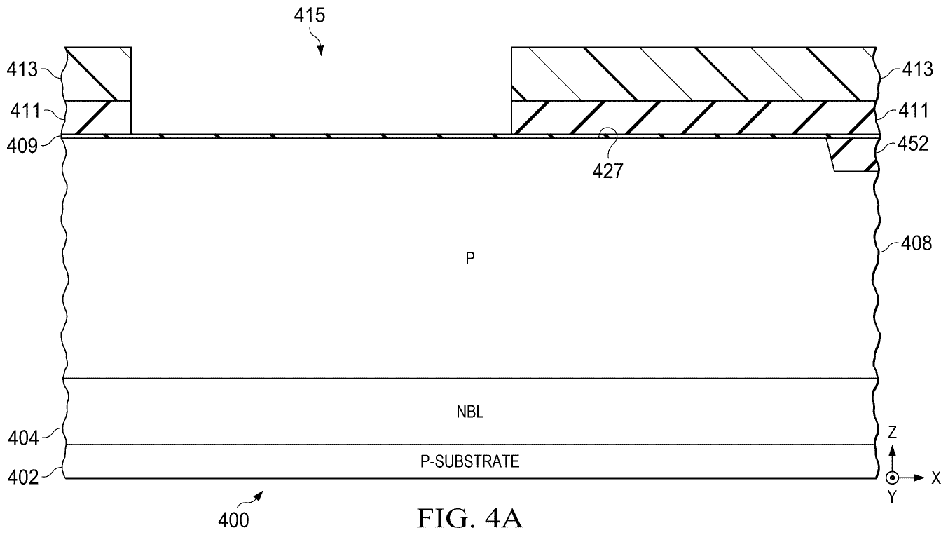

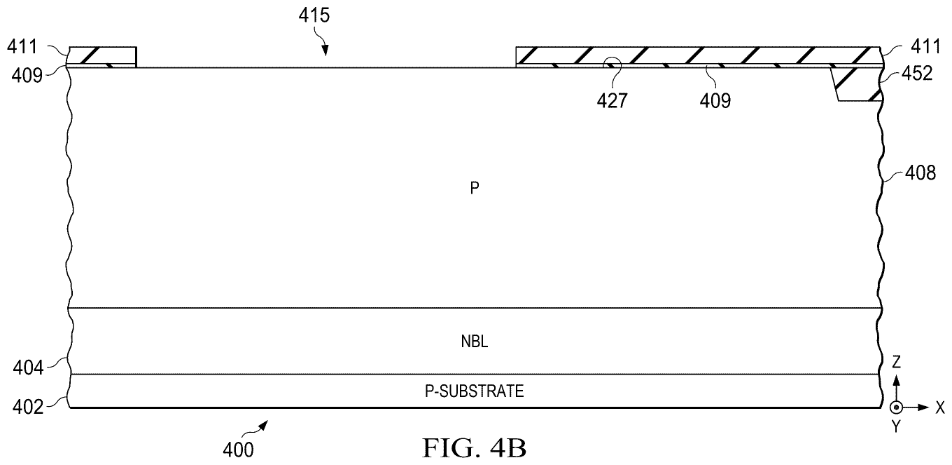

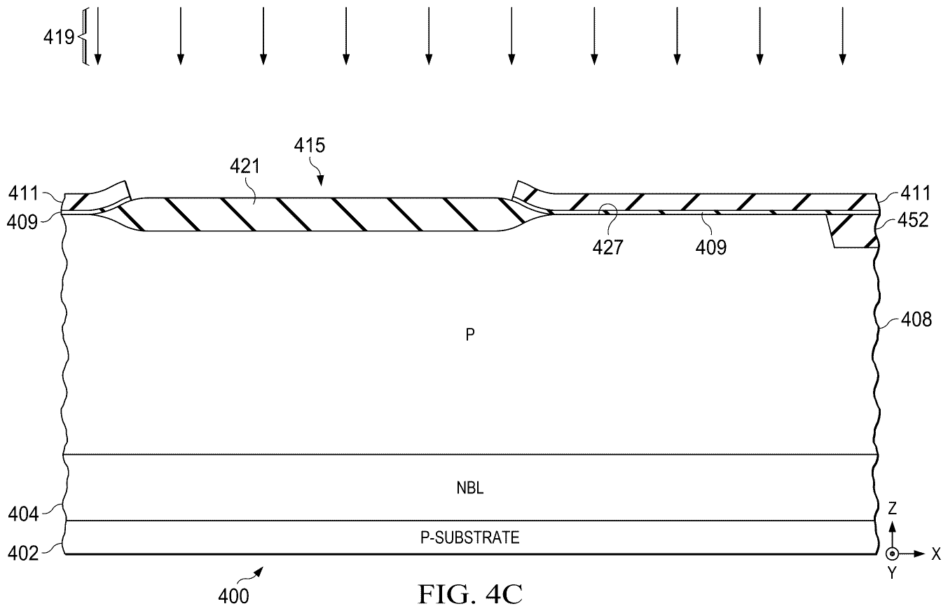

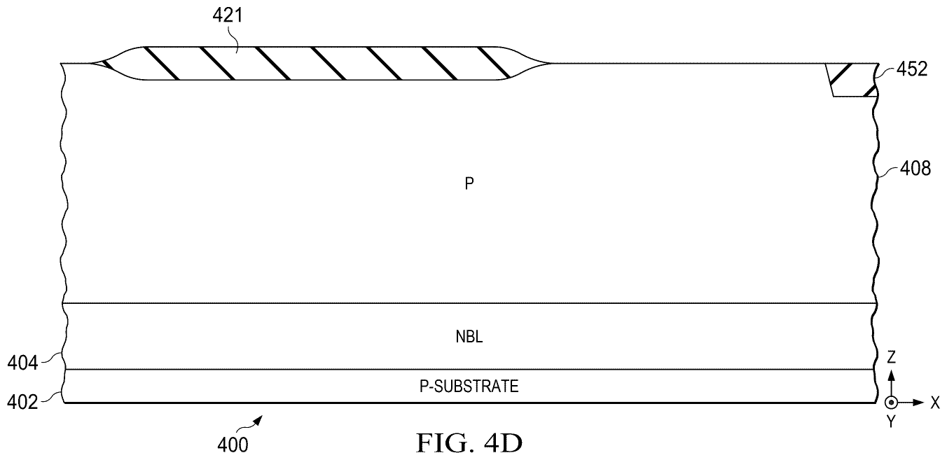

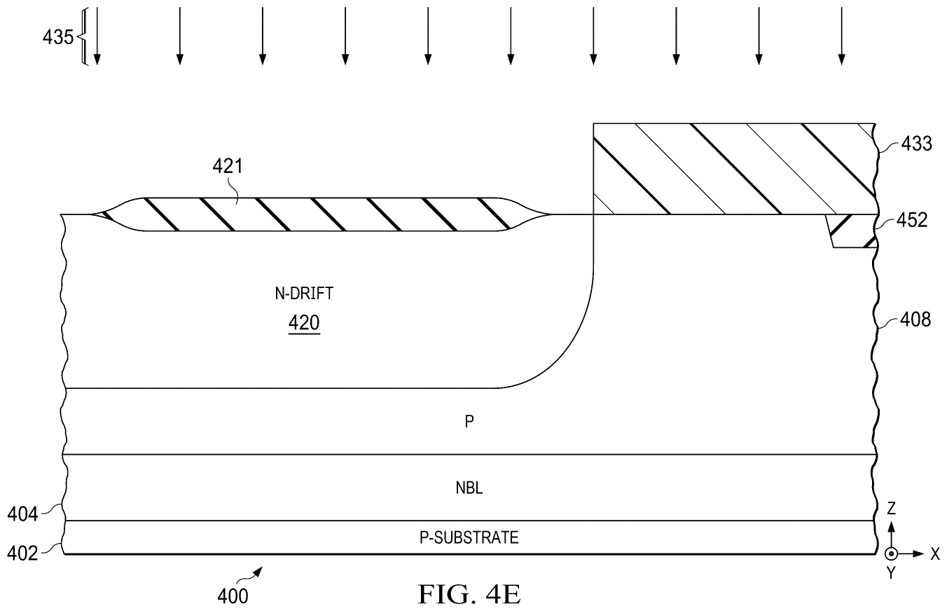

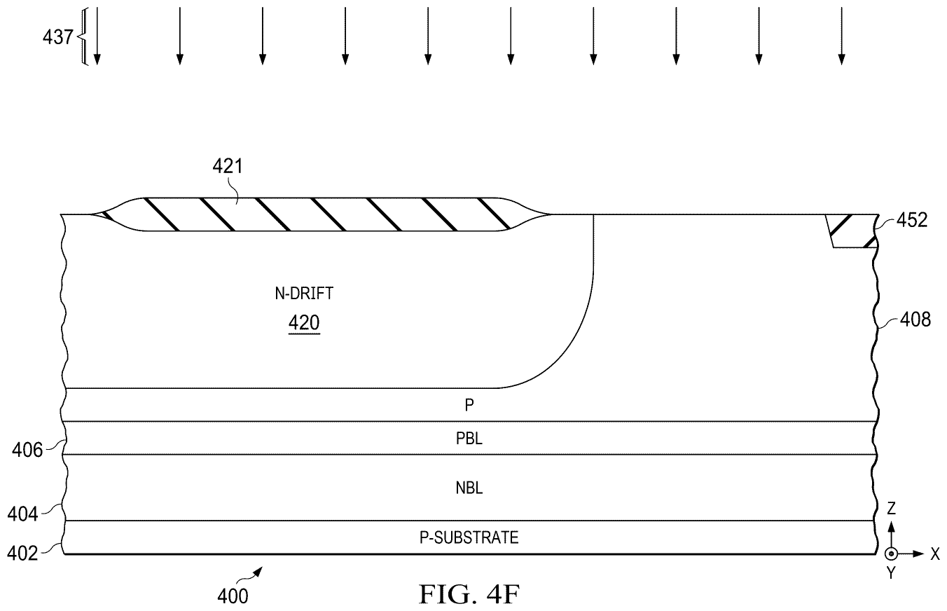

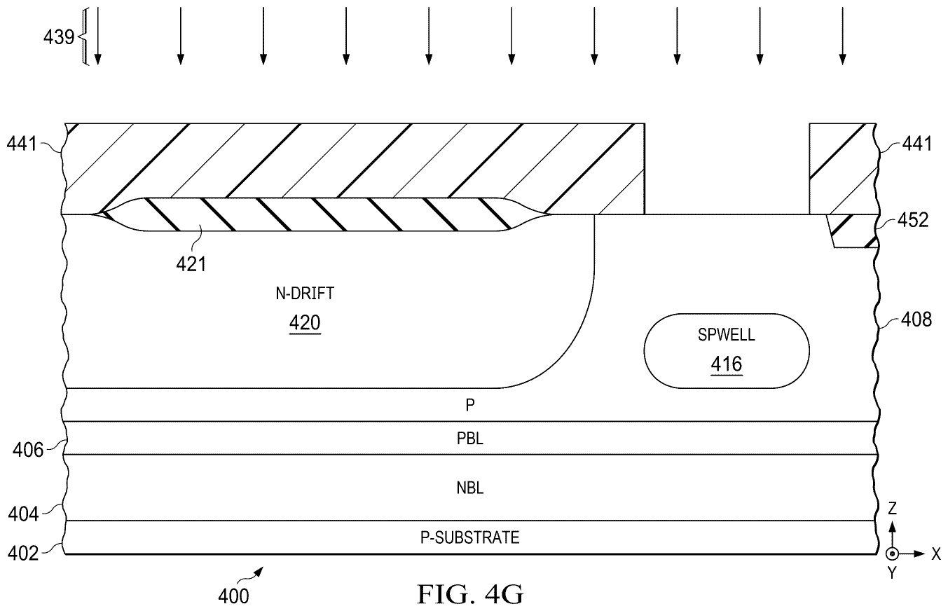

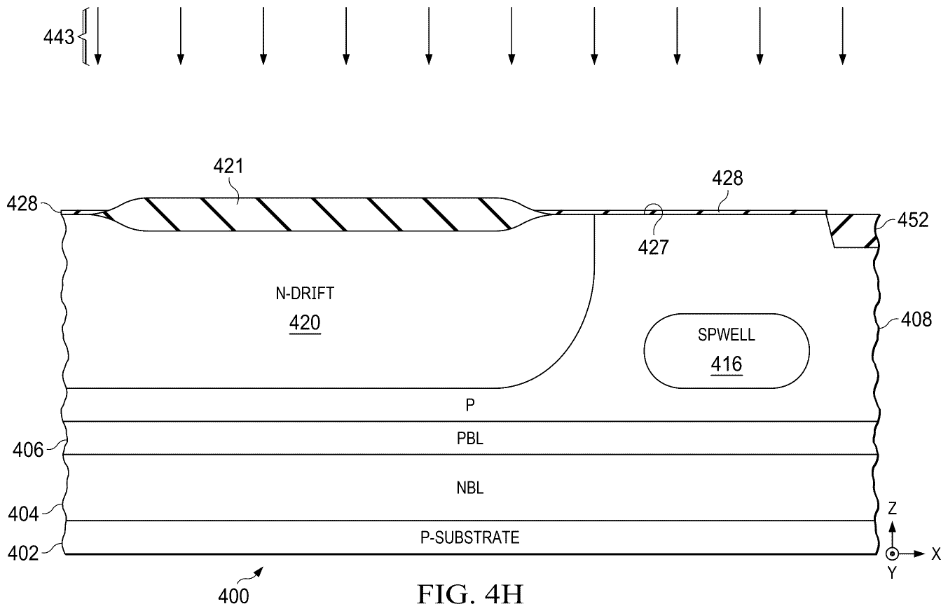

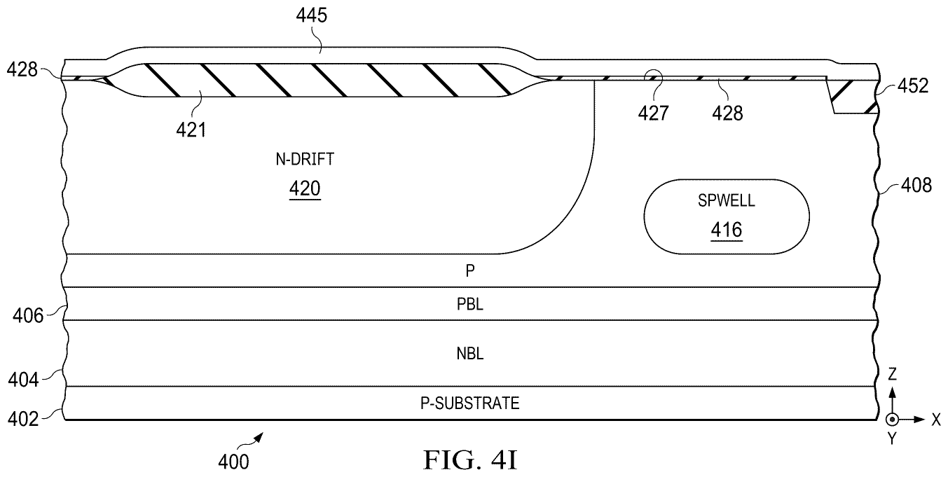

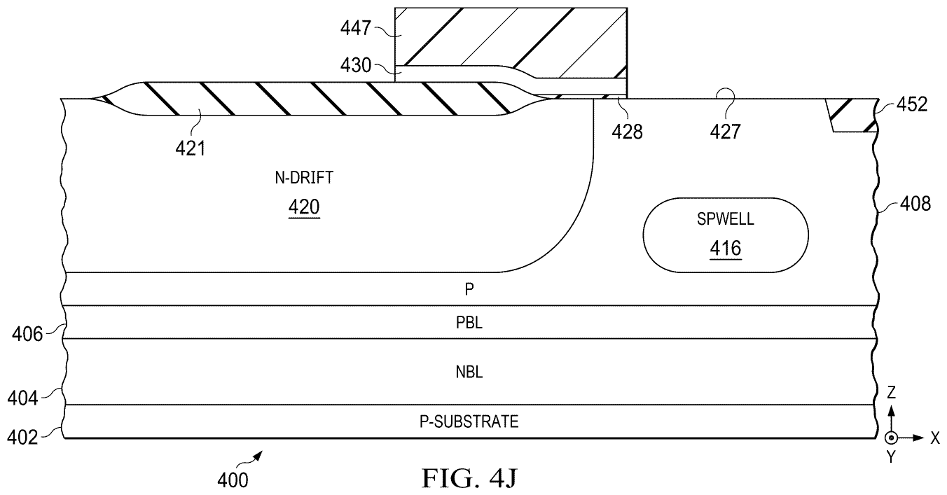

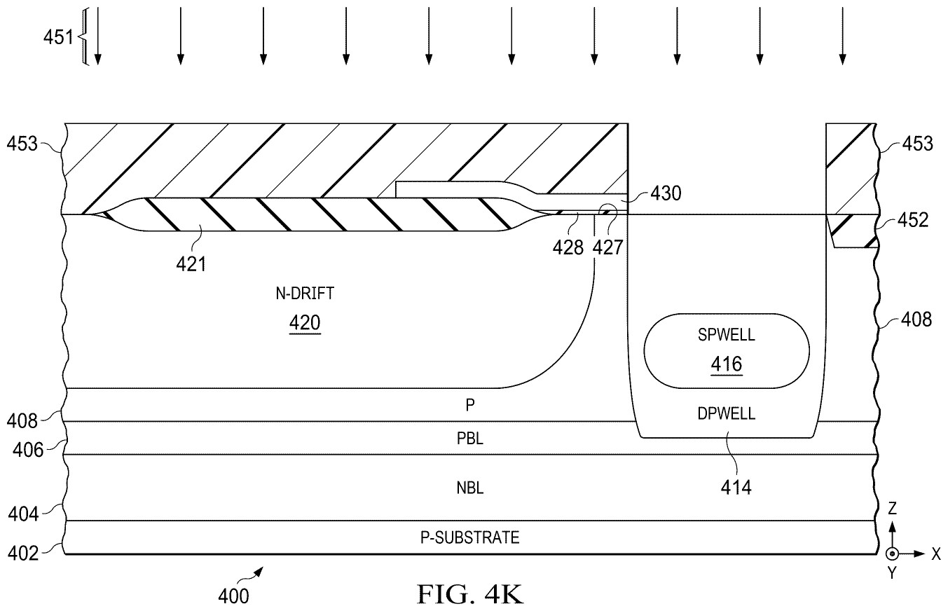

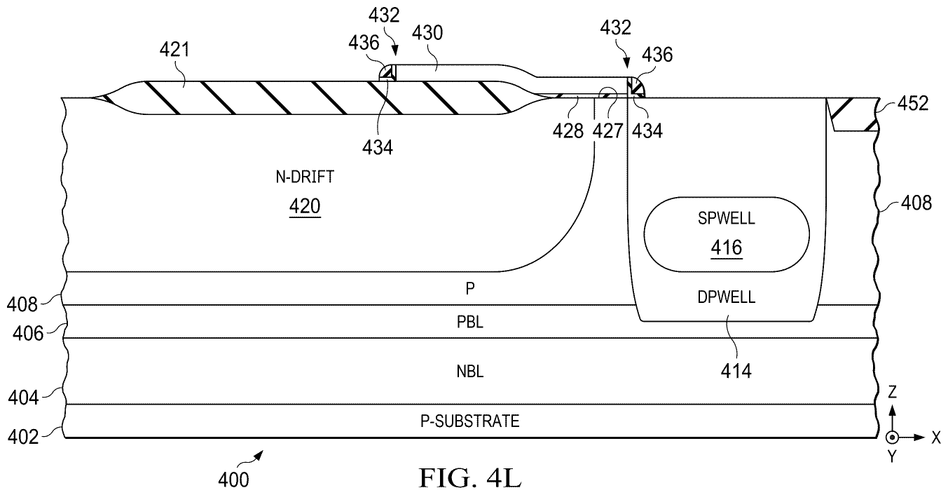

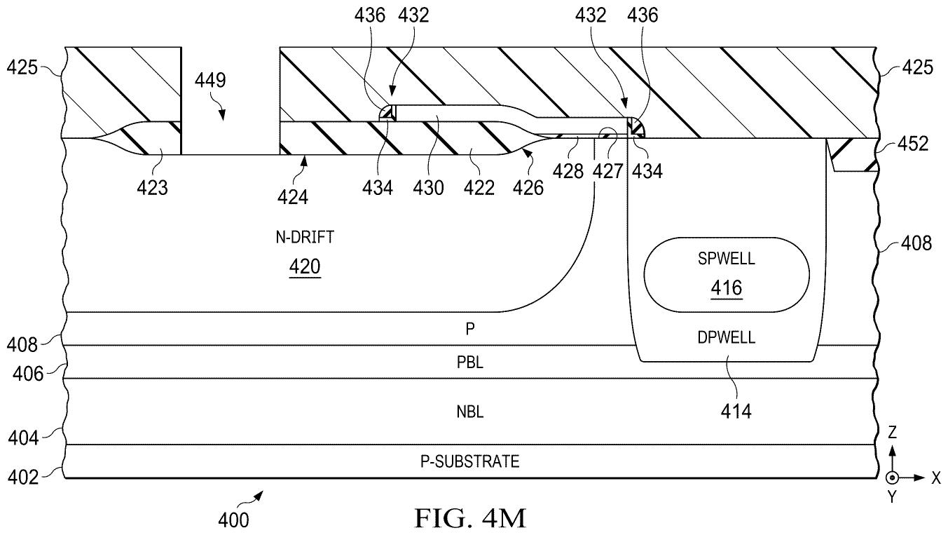

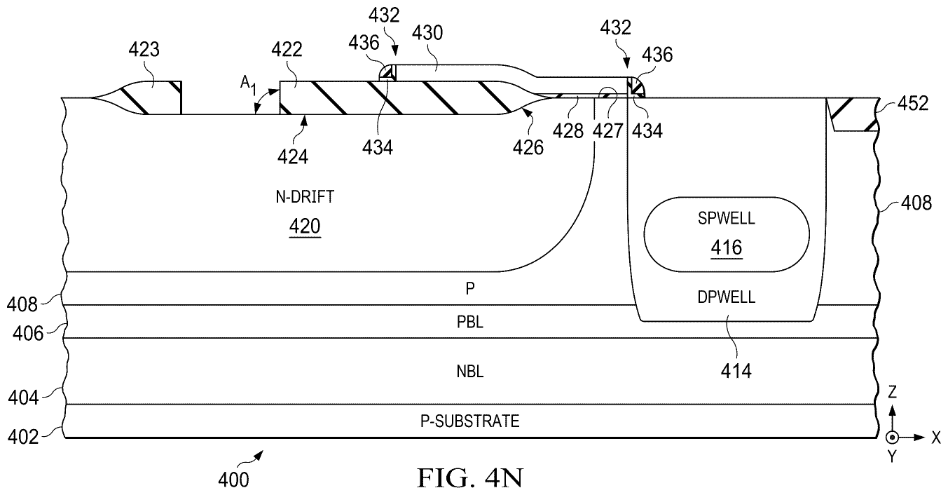

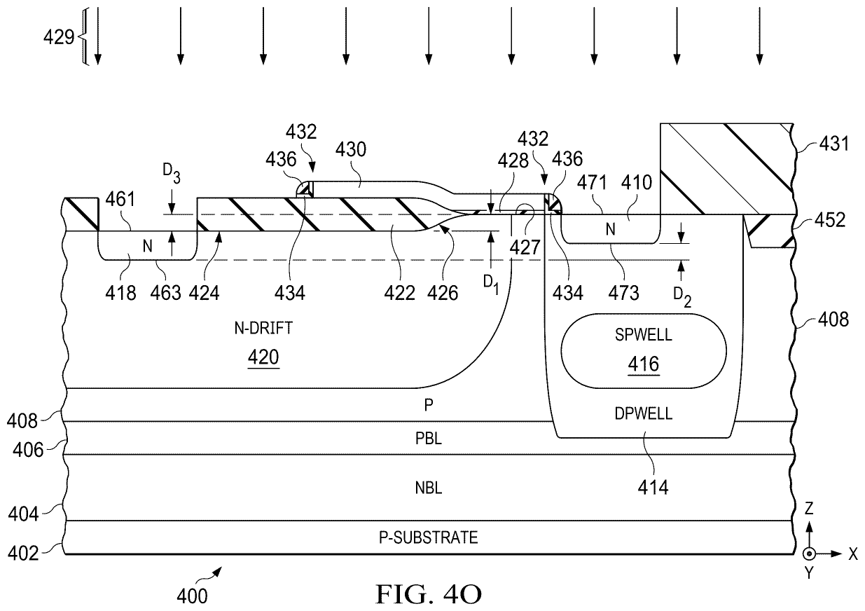

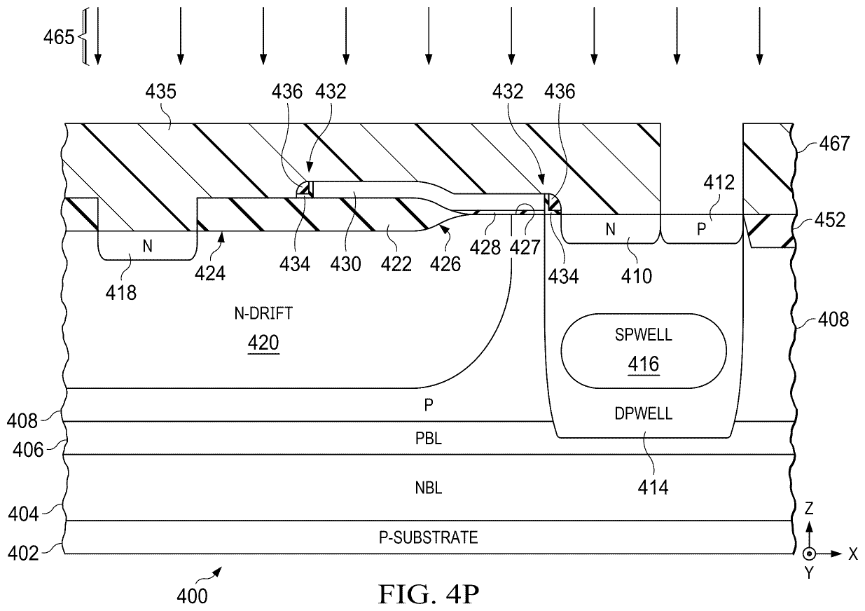

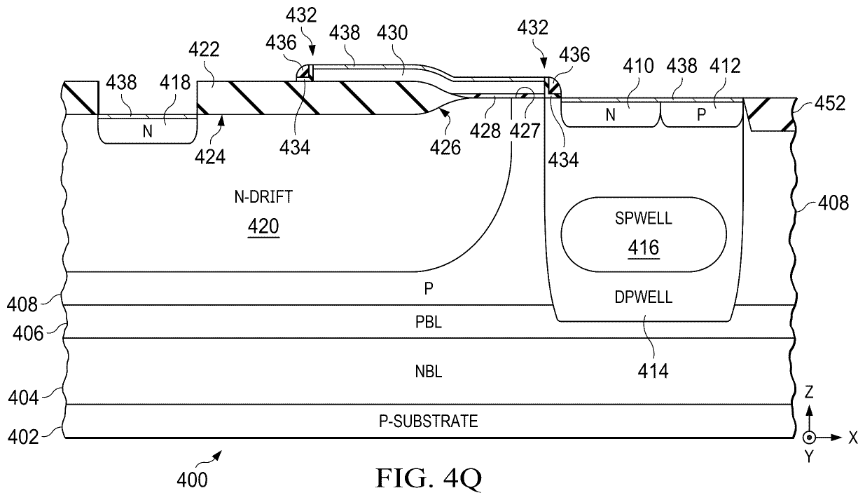

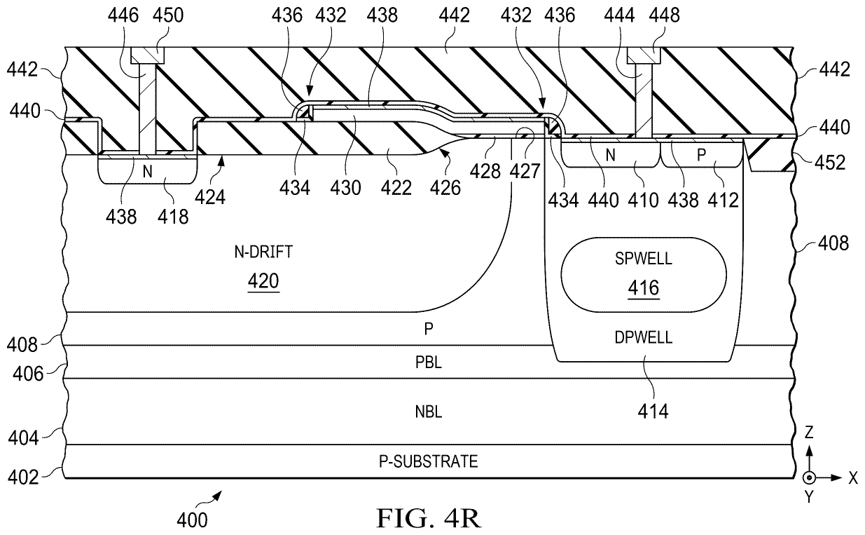

In some examples, e.g., as will be illustratively described in the context of FIGS. 1 and 2A-2Q, the first profile includes a first bird's beak profile and the second profile includes a second bird's beak profile different than the first bird's beak profile. While in some other examples, e.g., as will be illustratively described in the context of FIGS. 3 and 4A-4R, the first profile includes a profile substantially perpendicular to a surface of the semiconductor layer and the second profile includes a bird's beak profile.

In another example, a semiconductor device includes a semiconductor layer, drain and source regions disposed in the semiconductor layer, and a gate stack disposed between the drain and source regions. The semiconductor device also includes a field relief layer disposed between the drain region and source regions, and at least partially in the semiconductor layer, the field relief layer having a first end adjacent to the drain region with a first profile and a second end adjacent to the source region with a second profile, wherein the first profile is smaller in width, defined in a direction along a surface of the semiconductor layer, relative to the second profile.

Further, in some examples, the first profile may be defined relative to an edge of the drain region and the second profile includes a bird's beak profile. Moreover, in some examples, the drain region may be located at a depth from the surface of the semiconductor layer deeper than the source region. In some examples, a surface of the drain region may be recessed with respect to a surface of the source region. In some other examples, the term substantially perpendicular may be defined as the first profile having an angle of 90+/−20 degrees relative to the direction along the surface of the semiconductor layer.

In an additional example, a method of fabricating a semiconductor device includes forming an asymmetric field relief layer disposed partially in a semiconductor layer and partially above a surface of the semiconductor layer, the asymmetric field relief layer having a first end with a first profile and a second end with a second profile different than the first profile. The method also includes forming a drain region, a source region, and a gate stack, the drain region being proximate to the first end of the asymmetric field relief layer, the source region being proximate to the second end of the asymmetric field relief layer, and the gate stack being between the drain region and the source region and partially over the asymmetric field relief layer.

In some examples, forming the asymmetric field relief layer may further include forming an oxide-based layer on the surface of the semiconductor layer, and forming a nitride-based layer on the oxide-based layer. The nitride-based layer may be etched using a first mask that defines a field relief opening. The nitride-based layer may then be further etched using a second mask to form a first portion of the nitride-based layer on one side of the field relief opening and a second portion of the nitride-based layer on another side of the field relief opening, the first portion being thicker than the second portion. The method may then include thermally growing an oxide layer in the field relief opening to form the asymmetric field relief layer.

In other examples, after the nitride-based layer is etched using a first mask that defines the field relief opening, an oxide layer may be thermally grown in the field relief opening. Next, the nitride-based layer is removed. The oxide layer is then etched using a second mask that defines an opening corresponding to the drain region. The opening in the oxide layer may be used to form the drain region adjacent to the first end of the asymmetric field relief layer. In view of the thermally-grown oxide layer consuming a portion of the semiconductor layer (e.g., a portion of silicon converted to silicon oxide during the LOCOS process), a surface of the drain region (e.g., at the bottom of the opening in the oxide layer) may be recessed with respect to a surface of the source region (e.g., a surface of the semiconductor layer absent the LOCOS layer). In some examples, the drain region may be formed at a depth from the surface of the semiconductor layer deeper than the source region.

Still further, in some examples, the first profile of the first end of the asymmetric field relief layer may be defined (e.g., predetermined) before forming an oxide layer in the field relief opening, while in some other examples, the first profile of the first end of the asymmetric field relief layer may be defined (e.g., determined) after forming an oxide layer in the field relief opening.

Referring now to FIG. 1, a semiconductor device 100 having an asymmetric field relief layer, e.g., an asymmetric LOCOS layer, is shown. The semiconductor device 100 is illustrated in an example three-dimensional space with a first direction X, a perpendicular (orthogonal) second direction Y, and a third direction Z that is perpendicular (orthogonal) to the respective first and second directions X and Y. Structures or features along any two of these directions are orthogonal to one another.

While semiconductor device 100 is shown as including one LDMOS transistor, additional transistors (e.g., LDMOS and/or other transistor types) and/or other components that are not expressly shown may be integrated as part of semiconductor device 100 in various other examples. Also, while the LDMOS transistor in FIG. 1 is illustrated as an n-channel LDMOS transistor, in one or more alternative examples, a p-channel LDMOS transistor can be formed when n-type regions are substituted by p-type regions and p-type regions are substituted by n-type regions. As used herein, a region, layer, structure, or the like, referred to as being of “a first conductivity type” can be one of a p-type or an n-type, while a region, layer, structure, or the like, referred to as being of “an opposite second conductivity type” can be the other of a p-type or an n-type.

As shown, the semiconductor device 100 includes a semiconductor substrate 102, a first buried layer 104 disposed on the semiconductor substrate 102, a second buried layer 106 disposed on the first buried layer 104, and a semiconductor layer 108 disposed on the second buried layer 106. In some examples, the semiconductor layer 108 can be formed by an epitaxial process, and thus can be referred to as an epitaxial or “epi” layer 108. In the FIG. 1 example, the semiconductor substrate 102 is a p-type substrate (P-SUBSTRATE), the second buried layer 106 is p-type buried layer (PBL), and the semiconductor layer 108 is a p-type semiconductor layer, while the first buried layer 104 is an n-type buried layer (NBL). In some examples, the PBL 106 has a dopant concentration greater than the semiconductor layer 108 and can be used to implement reduced surface field (RESURF) principles for safe operating area (SOA) improvement in the semiconductor device 100. While two buried layers, e.g., the NBL 104 and the PBL 106, are shown in FIG. 1, other examples may include one or the other of the buried layers, or no buried layers.

The semiconductor device 100 also includes an n-type source region 110 and a p-type body contact region 112 adjacent the source region 110, both disposed in a deep p-type well (DPWELL) 114. The DPWELL 114 is disposed in the semiconductor layer 108. A shallow p-type well (SPWELL) 116 can be disposed within the DPWELL 114. In such examples, the DPWELL 114 can extend partially into the PBL 106. Still further, the semiconductor device 100 includes an n-type drain region 118 and a n-type drain drift (N-DRIFT) region 120. The N-DRIFT region 120 is disposed in the semiconductor layer 108, and the drain region 118 is disposed in the N-DRIFT region 120.

In some examples, the SPWELL 116 has a dopant density higher than that of the semiconductor layer 108. The SPWELL 116 increases a base doping level of the semiconductor layer 108 to suppress a parasitic lateral NPN bipolar transistor formed by n-type source/p-type body region/n-type drain, which may limit high current operation for the LDMOS transistor thus restricting the SOA of the LDMOS transistor.

The semiconductor device 100 further includes an asymmetric field relief layer 122 (also referred to, e.g., as an asymmetric LOCOS layer, an asymmetric dielectric layer, an asymmetric silicon dioxide layer, an asymmetric oxide-based layer, and the like) having a first end 124 adjacent (proximate) the drain region 118 and a second end 126 adjacent (proximate) the source region 110. The asymmetric field relief layer 122 is disposed partially below a top surface 127 of the semiconductor layer 108 in the N-DRIFT region 120 and partially above the top surface 127 of the semiconductor layer 108. As shown, the first end 124 of the asymmetric field relief layer 122 has a first profile and the second end 126 of the asymmetric field relief layer 122 has a second profile different than the first profile.

In the FIG. 1 example, a difference between the first profile of the first end 124 and the second profile of the second end 126 can be described in terms of slope, e.g., the first profile includes a first tapered portion (e.g., a first or drain-side bird's beak of the asymmetric field relief layer 122) having a first slope and the second profile includes a second tapered portion (e.g., a second or source-side bird's beak of the asymmetric field relief layer 122) having a second slope less than the first slope. Examples of dimensions of the slopes and methods for fabricating the same will be described below in the context of FIGS. 2A through 2Q. Additionally or alternatively, a difference between the first profile of the first end 124 and the second profile of the second end 126 can be described in terms of width, e.g., the first profile includes a first tapered portion (e.g., a first or drain-side bird's beak of the asymmetric field relief layer 122) having a first width (denoted as W₁) extending in the X direction and the second profile includes a second tapered portion (e.g., a second or source-side bird's beak of the asymmetric field relief layer 122) having a second width (denoted as W₂) extending in the X direction and greater than the first width. Examples of dimensions of the widths and methods for fabricating the same will be described below in the context of FIGS. 2A through 2Q.

In some other examples, the first tapered portion of the first end 124 of the asymmetric field relief layer 122 includes a top surface and a bottom surface that converge over a shorter distance in the X direction relative to a top surface and bottom surface of the second tapered portion of the second end 126 of the asymmetric field relief layer 122. For example, the top surface of the first tapered portion of the first end 124 is compressed or deformed relative to the bottom surface of the first tapered portion of the first end 124 and thus the top and bottom surfaces converge asymmetrically and over a relatively smaller distance in the X direction, while the top surface and the bottom surface of the second tapered portion of the second end 126 converge substantially symmetrically and over a relatively larger distance in the X direction.

One technical advantage for having the first (drain-side) end 124 of the asymmetric field relief layer 122 shorter in width, greater in slope, and/or having top and bottom surfaces that converge over a smaller distance as compared to the second (source-side) end 126 of the asymmetric field relief layer 122 is to enable the benefit of the relatively smooth transition of the second end 126 of the asymmetric field relief layer 122 with a later formed gate dielectric layer (e.g., gate dielectric layer 128 in FIG. 1) while preventing the first end 124 from encroaching into the drain region 118. Any such encroachment during formation would necessitate a lengthening (X direction) of the LDMOS transistor to move the drain region a larger distance from the asymmetric field relief layer 122. Recall that a LOCOS layer tends to provide BV improvement in the LDMOS transistor—however, any lengthening of the device comes at the expense of increased Rsp.

As further shown in FIG. 1, the tapered portion of the second end 126 of the asymmetric field relief layer 122 connects to the gate dielectric layer 128 disposed on a portion of the top surface 127 of the semiconductor layer 108. The gate dielectric layer 128 is part of a gate stack along with a gate electrode 130. The gate electrode 130 is disposed over the gate dielectric layer 128 and at least a portion of the asymmetric field relief layer 122. As shown in FIG. 1, the gate electrode 130 extends along the gate dielectric layer 128 from the DPWELL 114 and slopes upward in the Z direction along the slope of the second end 126 of the asymmetric field relief layer 122 before terminating at an edge along a top non-sloped surface of the asymmetric field relief layer 122 (e.g., prior to reaching the first end 124 of the asymmetric field relief layer 122). In some examples, the edge of the gate electrode 130 above the top non-sloped surface of the asymmetric field relief layer 122 may terminate closer to the source region 110 or closer to the drain region 118 as compared to where it is shown terminating in FIG. 1.

In some examples, the gate electrode 130 is a polysilicon material. In other examples, the gate electrode 130 is a metal or other suitable material. A channel region may be considered to extend across a portion of the semiconductor region 108 under the gate electrode 130 between the source region 110 and the drain region 118.

As further shown in FIG. 1, the semiconductor device 100 includes sidewall spacer structures 132 along the lateral sides of the gate electrode 130. The sidewall spacer structures 132 in one example include an oxide layer 134 and a nitride layer 136. In another example, a nitride-only (or oxide-only) sidewall spacer structure can be implemented.

The semiconductor device 100 also includes metal silicide layers 138 that respectively extend over the source region 110, the body contact region 112, the drain region 118, and the gate electrode 130. In addition, the semiconductor device 100 includes a nitride etch stop layer 140 that extends over portions of the metal silicide layers 138 and the sidewall spacer structures 132. The semiconductor device 100 can include a single or multilevel metallization structure, with a pre-metal dielectric (PMD) layer 142, conductive metal (e.g., tungsten) contacts 144 and 146 for a source region 110 and the drain region 118, as well as a conductive metal contact (not expressly shown) for the gate electrode 130. The illustrated portion of the metallization structure in FIG. 1 also shows metal interconnects 148 and 150 conductively coupled to the respective source and drain contacts (conductive metal contacts) 144 and 146. Lastly, in the FIG. 1 example, (a portion of) an STI layer 152 is shown disposed below the top surface 127 of the semiconductor layer 108 as an isolation region between the LDMOS transistor and another component (not expressly shown).

Referring now to FIGS. 2A-2Q, cross-sectional views are shown of a process flow for forming a semiconductor device 200 with an asymmetric field relief layer (e.g., an asymmetric LOCOS layer) in accordance with an example of the present disclosure. More particularly, the process flow of FIGS. 2A-2Q for the semiconductor device 200 may represent an example of the formation of the semiconductor device 100 with the asymmetric field relief layer 122 of FIG. 1. Accordingly, unless otherwise specified, reference numerals in the 200s in FIGS. 2A-2Q correspond to the same layers and structures with reference numerals in the 100s in FIG. 1 (e.g., a semiconductor substrate 202 in FIGS. 2A-2Q corresponds to semiconductor substrate 102 in FIG. 1, NBL 204 corresponds to NBL 104, and so on).

FIG. 2A depicts an intermediate stage of formation of the semiconductor device 200. As shown, the semiconductor device 200 includes a p-type semiconductor substrate (P-SUBSTRATE) 202 which may be implemented as a silicon wafer, a silicon-on-sapphire wafer, a silicon carbide wafer, or the like. In some examples, a p-type semiconductor layer 208 is epitaxially grown on the semiconductor substrate 202. Then, n-type dopants or impurities (e.g., phosphorus, etc.) are implanted in the semiconductor layer 208 to form an n-type buried layer (NBL) 204. In other examples, n-type dopants or impurities (e.g., phosphorus, etc.) are introduced to the p-type semiconductor substrate 202, and then a p-type semiconductor layer 208 is epitaxially grown on the semiconductor substrate 202. In other examples, the NBL 204 can be omitted. As further shown in the FIG. 2A example, an STI layer 252 is formed in the semiconductor layer 208 for electrical isolation between the LDMOS transistor being formed as part of the semiconductor device 200 and any adjacent component (not expressly shown). Also, while not expressly shown, another similar STI layer can be formed on the opposite side of the LDMOS transistor.

FIG. 2A further depicts initial portions of a LOCOS process for forming an asymmetric field relief layer (e.g., an asymmetric field relief layer 222 in FIG. 2D) partially above and partially below a top surface 227 of the semiconductor layer 208. For example, as shown, a pad oxide layer 209 (e.g., silicon dioxide) is formed on the semiconductor layer 208, e.g., using a thermal oxidation process or a deposition process such as chemical vapor deposition (CVD). In some examples, the pad oxide layer 209 can be about 20 nanometers (nm) in thickness in the Z direction. A silicon nitride layer 211 is then formed across the pad oxide layer 209. The silicon nitride layer 211 can be about 90 nm in thickness in the Z direction. Then, as shown in FIG. 2A, the silicon nitride layer 211 is etched (e.g., a dry etch) using a first mask layer 213 to form a field relief opening 215. The pad oxide layer 209 may be removed to expose a portion of the silicon of the semiconductor layer 208 below the pad oxide layer 209. In some examples, at least a portion of the pad oxide layer 209 may remain to protect the surface of the silicon during subsequent process steps (e.g., photolithography process, etch process). In some examples, the field relief opening 215 has a width in the X direction of about 300 to 500 nm (e.g., 400 nm).

Next, as shown in FIG. 2B, a second mask layer 217 is formed to cover the portion of the silicon nitride layer 211 to the left of the field relief opening 215 (drain region side of the LDMOS transistor being formed as part of the semiconductor device 200) while leaving uncovered the portion of the silicon nitride layer 211 to the right of the field relief opening 215 (source region side of the LDMOS transistor being formed as part of the semiconductor device 200). As shown in the FIG. 2B example, the second mask layer 217 extends into the field relief opening 215 and covers approximately half of the exposed portion of the pad oxide layer 209. However, in other examples, more or less of the exposed portion of the pad oxide layer 209 can be covered by the second mask layer 217.

The portion of the silicon nitride layer 211 to the right of the field relief opening 215 is then etched using a high selectivity (e.g., 1:10, oxide to nitride) etch process (e.g., a dry etch or a timed combination of dry and wet etches) such that the thickness in the Z direction of the portion of the silicon nitride layer 211 to the right of the field relief opening 215 is reduced relative to the portion of the silicon nitride layer 211 to the left of the field relief opening 215 (which is covered by the second mask layer 217). The second mask layer 217 and the remaining pad oxide layer 209 exposed in the field relief opening 215 are then removed. In some examples, some of the pad oxide layer 209 can remain.

By way of one example, when using a 1:10 selectivity etch process, and assuming the silicon nitride layer 211 (on both sides of the field relief opening 215) before the etch process is about 90 nm and the pad oxide layer 209 is about 20 nm, the etch process results in the portion of the silicon nitride layer 211 to the right of the field relief opening 215 having a thickness in the Z direction of about 30 nm (e.g., removing about 60 nm from the initial thickness) and the exposed portion of the pad oxide layer 209 (not covered by the second mask layer 217) having a thickness in the Z direction of about 14 nm (e.g., removing about 6 nm from the initial thickness). FIG. 2C depicts the different thicknesses in the Z direction of the silicon nitride layer 211, e.g., the portion of the silicon nitride layer 211 to the left of the field relief opening 215 (drain region side of the LDMOS transistor being formed as part of the semiconductor device 200) having a thickness T₁ and the portion of the silicon nitride layer 211 to the right of the field relief opening 215 (source region side of the LDMOS transistor being formed as part of the semiconductor device 200) having a thickness T₂ which is less than T₁ (e.g., T₁ equal to about 90 nm and T₂ equal to about 30 nm).

As shown in FIG. 2D, a thermal oxidation process 221 is applied at the next intermediate stage of the formation of the semiconductor device 200. The thermal oxidation process 221 is a relatively high-temperature (e.g., about 700 to about 1200 degrees Celsius (°C.)) furnace oxidation that causes the silicon area of the semiconductor layer 208, exposed in the field relief opening 215, to oxidize and form a relatively thick layer of silicon dioxide, e.g., an asymmetric field relief layer 222, partially above and partially below the top surface 227 of the semiconductor layer 208. Oxidation also occurs under the left and right side of the silicon nitride layer 211 adjacent the field relief opening 215. However, given the different thicknesses of the silicon nitride layer 211 to the left and right of the field relief opening 215, the profile of the silicon dioxide formed thereunder is different on the left side versus the right side.

More particularly, similar to asymmetric field relief layer 122 as described above with respect to FIG. 1, the asymmetric field relief layer 222 includes a first end 224 (left side of the field relief opening 215) having a first profile and a second end 226 (right side of the field relief opening 215) having a second profile different than the first profile. The first profile of the first end 224 includes a first tapered portion (e.g., a first or drain-side bird's beak of the asymmetric field relief layer 222) having a first slope S₁ and the second profile of the second end 226 includes a second tapered portion (e.g., a second or source-side bird's beak of the asymmetric field relief layer 222) having a second slope S₂ less than the first slope S₁. While each of the tapered portions of the first and second ends 224 and 226 have top surfaces and bottom surfaces that meet or substantially meet (e.g., the first end 224 having a top surface 223 and a bottom surface 225, and the second end 226 having a top surface 229 and a bottom surface 231), an average slope for the top and bottom surfaces or individual slopes of each surface can be selected based on the particular device characteristics. In some examples, slope S₁ can be about 110-130 degrees (e.g., as shown in FIG. 2D, Θ₁ measured counterclockwise relative to a non-tapered bottom surface of asymmetric field relief layer 222) and slope S₂ can be about 160-170 degrees (e.g., as shown in FIG. 2D, Θ₂ measured clockwise relative to the non-tapered bottom surface of asymmetric field relief layer 222).

Additionally or alternatively, a difference between the first profile of the first end 224 and the second profile of the second end 226 can be described in terms of width, e.g., the first profile includes a first tapered portion (e.g., a first or drain-side bird's beak of the asymmetric field relief layer 222) having a first width W₁ and the second profile includes a second tapered portion (e.g., a second or source-side bird's beak of the asymmetric field relief layer 222) having a second width W₂ greater than the first width W₁. In some examples, widths W₁ and W₂ scale with LOCOS thickness and can be calculated based on the above-defined slopes S₁ and S₂. As an example, for a LOCOS thickness (in the Z direction) of about 100 nm (denoted as T in FIG. 2D), width W₁ (in X direction) can be about 50-70 nm and width W₂ (in X direction) can be about 130-200 nm.

Also, as similarly described above in the context of FIG. 1, the top and bottom surfaces 223 and 225 of the first end 224 of the asymmetric field relief layer 222 converge over a shorter distance in the X direction relative to the top and bottom surfaces 229 and 231 of the second end 226 of the asymmetric field relief layer 222. For example, the top surface 223 of the first end 224 is compressed or deformed relative to the bottom surface 225 of the first end 224 and thus the top and bottom surfaces 223 and 225 converge asymmetrically, while the top and bottom surfaces 229 and 231 of the second end 226 converge substantially symmetrically. Further, in some examples, the non-tapered portion of the asymmetric field relief layer 222 (e.g., the portion of the asymmetric field relief layer 222 between the first end 224 and the second end 226) may have a thickness in the Z direction, from a substantially non-tapered top surface to a substantially non-tapered bottom surface, of about 50 to 150 nm.

The difference in the profiles of the first and second ends 224 and 226 of the asymmetric field relief layer 222 are caused by the differing thicknesses of the silicon nitride layer 211 on opposing sides of the field relief opening 215. Since a relatively thinner (T₂) silicon nitride layer 211 is formed on the right side of the field relief opening 215 (second end 226 of the asymmetric field relief layer 222), the silicon nitride yields (bends) to the expanding silicon dioxide formed during the LOCOS process—e.g., bending upward in the Z direction, however, without peeling away (separating) from the pad oxide layer 209—to form a substantially symmetric bird's beak. In comparison, a relatively thicker (T₁) silicon nitride layer 211 is formed on the left side of the field relief opening 215 (first end 224 of the asymmetric field relief layer 222). As such, the silicon nitride does not yield (or yields less) to the expanding silicon dioxide formed during the LOCOS process—e.g., causing formation of a bird's beak in the silicon dioxide that is shorter in width, greater in slope, and/or is otherwise compressed or deformed, relative to the bird's beak on the opposing side of the silicon dioxide. As described above, the differing profiles at each end of the asymmetric field relief layer 222 enables the benefit of a relatively smooth transition of the second end 226 of the asymmetric field relief layer 222 with a gate dielectric layer to be formed while preventing the first end 224 from encroaching into an area of the semiconductor layer 208 in which the drain region is to be formed. Recall that any such encroachment during formation would necessitate a lengthening (X direction) of the LDMOS transistor to move the drain region a greater distance from the asymmetric field relief layer 222 causing an increased Rsp.

Next, as shown in FIG. 2E, the silicon nitride layer 211, and portions of the pad oxide layer 209 that extend beyond the first and second ends 224 and 226, are removed leaving the asymmetric field relief layer 222.

In a next intermediate stage, as shown in FIG. 2F, an n-type drain drift (N-DRIFT) region 220 is formed in the semiconductor layer 208 below the asymmetric field relief layer 222. In the FIG. 2F example, a mask layer 233 is deposited on the semiconductor layer 208 exposing the intended drain drift region. An implantation process 235 is performed that forms the N-DRIFT region 220 by implanting phosphorus or other n-type dopants or impurities. In one example, the implantation process 235 includes four implants with a shallow implantation of phosphorous dopants at a low-level implantation energy of approximately 30 to 70 keV and a shallow implantation of arsenic at the same low-level implantation energy, followed by a mid-level implantation of phosphorus or arsenic at approximately 100 to 200 keV and a high energy phosphorus or arsenic implant at approximately 300 to 500 keV, where the implantation dose and energy can vary according to a desired voltage rating of a particular device.

Next, FIG. 2G illustrates formation of a p-type buried layer (PBL) 206. For example, as shown, an implantation process 237 is performed that implants boron or other p-type dopants into the p-type semiconductor layer 208 over the NBL 204. In one example, the implantation process 237 implants boron at a dose of about 1×10¹² cm⁻² to 1×10¹³ cm⁻² at an energy of about 400 keV to 3 MeV. In another example, the implantation process 237 can implant indium or other p-type dopants. In certain implementations for low-voltage transistors, the implantation process 237 is a blanket implantation without the use of an implant mask. In another implementation for high-voltage transistors, an implant mask can be used for selective implantation of the PBL 206. In one example, the implantation process 237 can be followed by one or more thermal processes to extend or diffuse the implanted p-type dopants below the N-DRIFT region 220 and activate the implanted p-type dopants. In other examples, the formation of PBL 206 can be omitted.

FIG. 2H illustrates formation of a shallow p-type well (SPWELL) 216. For example, as shown, an implantation process 239 is performed using an implant mask 241. In one example, the implantation process 239 implants p-type dopants to form the SPWELL 216 having a dopant density higher than that of the semiconductor layer 208. One technical advantage of the SPWELL 216 formation is to increase the base p-type doping level in the semiconductor layer 208 to suppress a parasitic lateral NPN bipolar transistor formed by an n-type source/p-type body region/n-type drain, which may limit high current operation for the LDMOS transistor being formed thus restricting the SOA of the LDMOS transistor.

In a next intermediate stage, as shown in FIG. 2I, a gate dielectric layer 228 is formed. In the FIG. 2I example, a gate dielectric formation process 243 is performed that forms the gate dielectric layer 228 over exposed portions of the top surface 227 of the semiconductor layer 208 by thermal oxidation or other suitable processing, such as a high temperature furnace operation or a rapid thermal anneal (RTA) process. The gate dielectric layer 228 thickness in the Z direction, in one example, is approximately 3 nm to 15 nm for silicon dioxide or a silicon oxynitride gate dielectric layer 228 can be formed that is slightly thinner but with a higher dielectric constant than that of silicon dioxide. In some examples, a gate dielectric layer 228 may be deposited (e.g., CVD process or atomic layer deposition (ALD) process) over the top surface 227 of the semiconductor layer 208, the asymmetric field relief layer 222, and the STI layer 152.

FIGS. 2J and 2K illustrate formation of a gate electrode 230. More particularly, FIG. 2J shows a deposition of a polycrystalline silicon (e.g., polysilicon) layer 245 over the asymmetric field relief layer 222, the gate dielectric layer 228, and the STI layer 252. In one example, the polysilicon layer 245 is formed using one or more silane-based precursors. Next, as shown in FIG. 2K, an etch mask layer 247 is used to etch the polysilicon layer 245 to form the gate electrode 230, as well as remove portions of the gate dielectric layer 228 other than the portion that is under the gate electrode 230. In one example, a plasma etch process is used to etch the polysilicon layer 245 followed by removal of the etch mask layer 247. A wet or dry cleaning process can then be used to clean exposed surfaces. In other examples, a metal gate or CMOS-based replacement gate electrode process can also be used to form the gate electrode 230.

The remaining portion of the gate dielectric layer 228 is part of a gate stack along with the gate electrode 230. The gate electrode 230 is formed over the gate dielectric layer 228 and at least a portion of the asymmetric field relief layer 222. As further shown in FIG. 2K, the gate electrode 230 extends along a top surface of the gate dielectric layer 228 and slopes upward in the Z direction along the second end 226 of the asymmetric field relief layer 222 before terminating at an edge along a top non-sloped surface of the asymmetric field relief layer 222 (prior to reaching the first end 224 of the asymmetric field relief layer 222). In other examples, the edge of the gate electrode 230 above the top non-sloped surface of the asymmetric field relief layer 222 may terminate closer to the first end 224 or closer to the second end 226 as compared to where it is shown terminating in the FIG. 2K example.

FIG. 2L illustrates formation of a deep p-type well (DPWELL) 214. For example, as shown, an implantation process 251 is performed using an implant mask 253. In one example, the implantation process 251 implants p-type dopants into a portion of the semiconductor layer 208 laterally adjacent to or outward of the N-DRIFT region 220 to form the DPWELL 214. The p-type dopants implanted by the implantation process 251 may include boron, indium or other suitable p-type dopants. In one example, a boron implantation is performed with an energy of about 20 keV and a dose of about 8×10¹³ cm⁻² to 3.0×10¹⁴ cm⁻² (e.g., approximately 1.5×10¹⁴ cm²). An angled implant can be used such as at a tilt angle of less than 5 degrees (e.g., 2 degrees). In some examples using an angled implant, or otherwise due to diffusion, DPWELL 214 can underlap (not expressly shown) the gate stack (e.g., gate dielectric layer 228 and gate electrode 230). In another example, the DPWELL 214 formation can include a shallow implant with a boron dose of approximately 1×10¹⁴ cm⁻² at an implant energy of approximately 30 keV, a boron implant with a dose of approximately 1×10¹⁵ cm⁻² at an implant energy of approximately 30 keV, and a high energy boron implant with a dose of approximately 1×10¹³ cm⁻² at an implant energy of approximately 600 keV to 1400 keV. Implant mask 253 is then removed.

Next, FIG. 2M illustrates formation of sidewall spacer structures 232 along the lateral sides of the gate electrode 230. The sidewall spacer structures 232, in the FIG. 2M example, include an oxide layer 234 and a nitride layer 236. In one example, an oxide layer and a nitride layer are deposited over the entire wafer surface (not expressly shown), followed by a blanket anisotropic plasma etch process that removes portions of the oxide layer and portions of the nitride layer to form the sidewall spacer structures 232. In another example, nitride-only (or oxide-only) sidewall spacer structures can be implemented. Although not explicitly illustrated in FIG. 2M, prior to forming the sidewall spacer structures 232, one or more implant processes can be done to introduce n-type dopants in the DPWELL 214—e.g., under the sidewall spacer structures 232. The n-type region formed as a result of the one or more implant processes extends along the top side of the DPWELL 214 and provides electrical connection between the channel under the gate stack and a later formed n-type source region (e.g., source region 210).

In a next intermediate stage, as shown in FIG. 2N, a source region 210 and a drain region 218 are formed in the semiconductor layer 208 with an n-type dopant(s). More particularly, an implantation process 255 is performed with an implant mask 257 to implant the source region 210 in the DPWELL 214 and the drain region 218 in the N-DRIFT region 220. In some examples, the source/drain implant is relatively shallow and thus does not penetrate the gate stack (e.g., gate dielectric layer 228 and gate electrode 230) and/or the asymmetric field relief layer 222 (e.g., the asymmetric field relief layer with its full thickness T depicted in FIG. 2D). Moreover, the drain region 218, in one example, contains an average dopant density at least 100 times that of the N-DRIFT region 220. In some examples using an angled implant, or otherwise due to diffusion, source region 210—while remaining within the DPWELL 214—can underlap (not expressly shown) the gate stack (e.g., gate dielectric layer 228 and gate electrode 230). In some examples, drain region 218 can underlap the first end 224 of asymmetric field relief layer 222.

FIG. 2O illustrates formation of a body contact region 212 in the semiconductor layer 208 with a p-type dopant(s). More particularly, an implantation process 259 is performed with an implant mask 261 to implant the body contact region 212 in the DPWELL 214 adjacent the source region 210.

Next, FIG. 2P illustrates formation of a metal silicide layers 238 that respectively extend over the source region 210, the body contact region 212, the drain region 218, and the gate electrode 230. In some examples, a metal silicide process includes depositing a metal layer (not expressly shown), for example, using a blanket deposition process. In some examples, a silicide-blocking layer may be formed prior to depositing the metal layer to define areas exposed to the blanket deposition process. The semiconductor device 200 is then heated to form the metal silicide layers 238 over the intended areas (e.g., the source region 210, the body contact region 212, the drain region 218, and the gate electrode 230) and unreacted metal is subsequently removed in a wet stripping process.

Lastly, FIG. 2Q shows formation of a nitride etch stop layer 240 that extends over portions of the metal silicide layers 238 and the sidewall spacer structures 232, as well as a pre-metal dielectric (PMD) layer 242, conductive metal (e.g., tungsten) contacts 244 and 246 for a source region 210 and the drain region 218, and a conductive metal contact (not expressly shown) for the gate electrode 230. Still further, as shown, metal interconnects 248 and 250 are formed and conductively coupled to the respective source and drain contacts (conductive metal contacts 244 and 246).

Following the process flow of FIGS. 2A-2Q, the finished wafer can then be separated (e.g., die singulation) to separate individual semiconductor dies from the starting wafer, and the dies can then be packaged to form integrated circuits or other packaged semiconductor devices.

Referring now to FIG. 3, a semiconductor device 300 having an asymmetric field relief layer, e.g., an asymmetric LOCOS layer, is shown. The semiconductor device 300 is illustrated in an example three-dimensional space with a first direction X, a perpendicular (orthogonal) second direction Y, and a third direction Z that is perpendicular (orthogonal) to the respective first and second directions X and Y. Structures or features along any two of these directions are orthogonal to one another.

While semiconductor device 300 is shown as including one LDMOS transistor, additional transistors (e.g., LDMOS and/or other transistor types) and/or other components that are not expressly shown may be integrated as part of semiconductor device 300 in various other examples. Also, while the LDMOS transistor in FIG. 3 is illustrated as an n-channel LDMOS transistor, in one or more alternative examples, a p-channel LDMOS transistor can be formed when n-type regions are substituted by p-type regions and p-type regions are substituted by n-type regions. As used herein, a region, layer, structure, or the like, referred to as being of “a first conductivity type” can be one of a p-type or an n-type, while a region, layer, structure, or the like, referred to as being of “an opposite second conductivity type” can be the other of a p-type or an n-type.

As shown, the semiconductor device 300 includes a semiconductor substrate 302, a first buried layer 304 disposed on the semiconductor substrate 302, a second buried layer 306 disposed on the first buried layer 304, and a semiconductor layer 308 disposed on the second buried layer 306. In some examples, the semiconductor layer 308 can be formed by an epitaxial process, and thus can be referred to as an epitaxial or “epi” layer 308. In the FIG. 3 example, the semiconductor substrate 302 is a p-type substrate (P-SUBSTRATE), the second buried layer 306 is p-type buried layer (PBL), and the semiconductor layer 308 is a p-type semiconductor layer, while the first buried layer 304 is an n-type buried layer (NBL). In some examples, the PBL 306 has a dopant concentration greater than the semiconductor layer 308 and can be used to implement reduced surface field (RESURF) principles for safe operating area (SOA) improvement in the semiconductor device 300. While two buried layers, e.g., the NBL 304 and the PBL 306, are shown in FIG. 3, other examples may include one or the other of the buried layers, or no buried layers.

The semiconductor device 300 also includes an n-type source region 310 and a p-type body contact region 312 adjacent the source region 310, both disposed in a deep p-type well (DPWELL) 314. The DPWELL 314 is disposed in the semiconductor layer 308. A shallow p-type well (SPWELL) 316 can be disposed within the DPWELL 314. In such examples, the DPWELL 314 can extend partially into the PBL 306. Still further, the semiconductor device 300 includes an n-type drain region 318 and a n-type drain drift (N-DRIFT) region 320. The N-DRIFT region 320 is disposed in the semiconductor layer 308, and the drain region 318 is disposed in the N-DRIFT region 320.

In some examples, the SPWELL 316 has a dopant density higher than that of the semiconductor layer 308. The SPWELL 316 increases a base doping level of the semiconductor layer 308 to suppress a parasitic lateral NPN bipolar transistor formed by n-type source/p-type body region/n-type drain, which may limit high current operation for the LDMOS transistor thus restricting the SOA of the LDMOS transistor.

The semiconductor device 300 further includes an asymmetric field relief layer 322 (also referred to, e.g., as an asymmetric LOCOS layer, an asymmetric dielectric layer, an asymmetric silicon dioxide layer, an asymmetric oxide-based layer, and the like) having a first end 324 adjacent (proximate) the drain region 318 and a second end 326 adjacent (proximate) the source region 310. The asymmetric field relief layer 322 is disposed partially below a top surface 327 of the semiconductor layer 308 in the N-DRIFT region 320 and partially above the top surface 327 of the semiconductor layer 308. As shown, the first end 324 of the asymmetric field relief layer 322 has a first profile and the second end 326 of the asymmetric field relief layer 322 has a second profile different than the first profile.

A difference between the first profile of the first end 324 and the second profile of the second end 326 of the semiconductor device 300 of FIG. 3 can be described, as shown, in terms of the first end 324 having a profile substantially perpendicular to the top surface 327 of the semiconductor layer 308 and the second end 326 including a bird's beak profile. Additionally, the drain region 318 is located at a depth in the Z direction from the top surface 327 of the semiconductor layer 308 deeper than the source region 310. In some examples, a top surface of the drain region may be recessed with respect to a top surface of the source region. Examples of depth dimensions will be described below in the context of FIGS. 4A-4R.

Similar to the semiconductor device 100 described with reference to FIG. 1, one technical advantage for having the first (drain-side) end 324 of the asymmetric field relief layer 322 have the profile shown in FIG. 3 is to enable the benefit of the relatively smooth transition of the second end 326 of the asymmetric field relief layer 322 with a gate dielectric layer (e.g., a gate dielectric layer 328 in FIG. 3) while preventing the first end 324 from encroaching into the drain region 318. Any such encroachment during formation would necessitate a lengthening (X direction) of the LDMOS transistor to move the drain region a greater distance from the asymmetric field relief layer 322 causing an increased Rsp.

As further shown in FIG. 3, the tapered portion of the second end 326 of the asymmetric field relief layer 322 connects to the gate dielectric layer 328 disposed on a portion of the top surface 327 of the semiconductor layer 308. The gate dielectric layer 328 is part of a gate stack along with a gate electrode 330. The gate electrode 330 is disposed over the gate dielectric layer 328 and at least a portion of the asymmetric field relief layer 322. As shown in FIG. 3, the gate electrode 330 extends along the gate dielectric layer 328 from the DPWELL 314 and slopes upward in the Z direction along the slope of the second end 326 of the asymmetric field relief layer 322 before terminating at an edge along a top non-sloped surface of the asymmetric field relief layer 322 (e.g., prior to reaching the first end 324 of the asymmetric field relief layer 322). In some examples, the edge of the gate electrode 330 above the top non-sloped surface of the asymmetric field relief layer 322 may terminate closer to the source region 310 or closer to the drain region 318 as compared to where it is shown terminating in FIG. 3.

In some examples, the gate electrode 330 is a polysilicon material. In other examples, the gate electrode 330 is a metal or other suitable material. A channel region may be considered to extend across a portion of the semiconductor layer 308 under the gate electrode 330 between the source region 310 and the drain region 318.

As further shown in FIG. 3, the semiconductor device 300 includes sidewall spacer structures 332 along the lateral sides of the gate electrode 330. The sidewall spacer structures 332 in one example include an oxide layer 334 and a nitride layer 336. In another example, a nitride-only (or oxide-only) sidewall spacer structure can be implemented.

The semiconductor device 300 also includes metal silicide layers 338 that respectively extend over the source region 310, the body contact region 312, the drain region 318, and the gate electrode 330. In addition, the semiconductor device 300 includes a nitride etch stop layer 340 that extends over portions of the metal silicide layers 338 and the sidewall spacer structures 332. The semiconductor device 300 can include a single or multilevel metallization structure, with a pre-metal dielectric (PMD) layer 342, conductive metal (e.g., tungsten) contacts 344 and 346 for a source region 310 and the drain region 318, as well as a conductive metal contact (not expressly shown) for the gate electrode 330. The illustrated portion of the metallization structure in FIG. 3 also shows metal interconnects 348 and 350 conductively coupled to the respective source and drain contacts (conductive metal contacts 344 and 346). Lastly, in the FIG. 3 example, (a portion of) an STI layer 352 is shown disposed below the top surface 327 of the semiconductor layer 308 as an isolation region between the LDMOS transistor and another component (not expressly shown).

Referring now to FIGS. 4A-4R, cross-sectional views are shown of a process flow for forming a semiconductor device 400 with an asymmetric field relief layer (e.g., an asymmetric LOCOS layer) in accordance with an example of the present disclosure. More particularly, the process flow of FIGS. 4A-4R for the semiconductor device 400 may represent an example of the formation of the semiconductor device 300 with the asymmetric field relief layer 322 of FIG. 3. Accordingly, unless otherwise specified, reference numerals in the 400s in FIGS. 4A-4R correspond to the same layers and structures with reference numerals in the 300s in FIG. 3 (e.g., a semiconductor substrate 402 in FIGS. 4A-4R corresponds to semiconductor substrate 302 in FIG. 3, NBL 404 corresponds to NBL 304, and so on).

FIG. 4A depicts an intermediate stage of formation of the semiconductor device 400. As shown, the semiconductor device 400 includes a p-type semiconductor substrate (P-SUBSTRATE) 402 which may be implemented as a silicon wafer, a silicon-on-sapphire wafer, a silicon carbide wafer, or the like. In some examples, a p-type semiconductor layer 408 is epitaxially grown on the semiconductor substrate 402. Then, n-type dopants or impurities (e.g., phosphorus, etc.) are implanted in the semiconductor layer 408 to form an n-type buried layer (NBL) 404. In other examples, n-type dopants or impurities (e.g., phosphorus, etc.) are introduced to the p-type semiconductor substrate 402, and then a p-type semiconductor layer 208 is epitaxially grown on the semiconductor substrate 402. In other examples, the NBL 404 can be omitted. As further shown in the FIG. 4A example, an STI layer 452 is formed in the semiconductor layer 408 for electrical isolation between the LDMOS transistor being formed as part of the semiconductor device 400 and any adjacent component (not expressly shown). Also, while not expressly shown, another similar STI layer can be formed on the opposite side of the LDMOS transistor.

FIG. 4A further depicts initial portions of a LOCOS process for forming an asymmetric field relief layer (e.g., an asymmetric field relief layer 422 in FIG. 4M) partially above and partially below a top surface 427 of the semiconductor layer 408. For example, as shown, a pad oxide layer 409 (e.g., silicon dioxide) is formed on the semiconductor layer 408, e.g., using a thermal oxidation process or a deposition process such as chemical vapor deposition (CVD). In some examples, the pad oxide layer 409 can be about 20 nanometers (nm) in thickness in the Z direction. A silicon nitride layer 411 is then formed across the pad oxide layer 409. The silicon nitride layer 411 can be about 90 nm in thickness in the Z direction. Then, as shown in FIG. 4A, the silicon nitride layer 411 is etched (e.g., a dry etch) using a first mask layer 413 to form a field relief opening 415. The pad oxide layer 409 may be removed to expose a portion of the silicon of the semiconductor layer 408 below the pad oxide layer 409. In some examples, at least a portion of the pad oxide layer 409 may remain. The first mask layer 413 and the remaining pad oxide layer 409 exposed in the field relief opening 415 may be then removed as shown in FIG. 4B. In some examples, some of the pad oxide layer 409 can remain.

As shown in FIG. 4C, a thermal oxidation process 419 is applied at the next intermediate stage of the formation of the semiconductor device 400. The thermal oxidation process 419 is a relatively high-temperature (e.g., about 700 to about 1200 degrees Celsius (°C.)) furnace oxidation that causes the silicon area of the semiconductor layer 408, exposed in the field relief opening 415, to oxidize and form a relatively thick layer of silicon dioxide, e.g., a symmetric field relief layer 421, partially above and partially below the top surface 427 of the semiconductor layer 408. Oxidation also occurs under the left and right sides of the silicon nitride layer 411 adjacent the field relief opening 415 forming substantially symmetrical bird's beaks on the left and right sides of the silicon nitride layer 411. The silicon nitride layer 411 is then removed as shown in FIG. 4D.

In a next intermediate stage, as shown in FIG. 4E, an n-type drain drift (N-DRIFT) region 420 is formed in the semiconductor layer 408 below the symmetric field relief layer 421. In the FIG. 4E example, a mask layer 433 is deposited on the semiconductor layer 408 exposing the intended drain drift region. An implantation process 435 is performed that forms the n-type N-DRIFT region 420 by implanting phosphorus or other n-type dopants or impurities. In one example, the implantation process 435 may be the same or similar to the N-DRIFT implantation process 235 or alternatives for semiconductor device 200.

Next, FIG. 4F illustrates formation of a p-type buried layer (PBL) 406. For example, as shown, an implantation process 437 is performed that implants boron or other p-type dopants into the p-type semiconductor layer 408 over the NBL 404. In one example, the implantation process 437 may be the same or similar to the PBL implantation process 237 or alternatives described for semiconductor device 200. In other examples, the formation of PBL 406 can be omitted.

FIG. 4G illustrates formation of a shallow p-type well (SPWELL) 416. For example, as shown, an implantation process 439 is performed using an implant mask 441. In one example, the implantation process 439 may be the same or similar to the SPWELL implantation process 239 or alternatives described for semiconductor device 200.

In a next intermediate stage, as shown in FIG. 2H, a gate dielectric layer 428 is formed over exposed portions of the top surface 427 of the semiconductor layer 408. using a gate dielectric formation process 443. In one example, the gate dielectric formation process 443 may be the same or similar manner to the gate dielectric layer formation process 243 or alternatives described for semiconductor device 200.

FIGS. 4I and 4J illustrate formation of a gate electrode 430. More particularly, FIG. 4I shows a deposition of a polycrystalline silicon (e.g., polysilicon) layer 445 over the symmetric field relief layer 421, the gate dielectric layer 428, and the STI layer 452. In one example, the polysilicon layer 445 is formed using one or more silane-based precursors. Next, as shown in FIG. 4J, an etch mask layer 447 is used to etch the polysilicon layer 445 to form the gate electrode 430, as well as remove portions of the gate dielectric layer 428 other than the portion that is under the gate electrode 430. In one example, a plasma etch process is used to etch the polysilicon layer 445 followed by removal of the etch mask layer 447. A wet or dry cleaning process can then be used to clean exposed surfaces. In other examples, a metal gate or CMOS-based replacement gate electrode process can also be used to form the gate electrode 430.

The remaining portion of the gate dielectric layer 428 is part of a gate stack along with the gate electrode 430. The gate electrode 430 is formed over the gate dielectric layer 428 and at least a portion of the asymmetric field relief layer 422 terminating at an edge along the top surface of the symmetric field relief layer 421. In other examples, the edge of the gate electrode 430 can terminate at a different location along the top surface of the symmetric field relief layer 421 than shown in FIG. 4J.

FIG. 4K illustrates formation of a deep p-type well (DPWELL) 414. For example, as shown, an implantation process 451 is performed using an implant mask 453. In one example, the implantation process 451 implants p-type dopants into a portion of the semiconductor layer 408 laterally adjacent to or outward of the N-DRIFT region 420 to form the DPWELL 414. The implantation process 451 may be the same or similar to the DPWELL implantation process 251 or alternatives described for semiconductor device 200. For instance, in some examples using an angled implant, or otherwise due to diffusion, DPWELL 414 can underlap (not expressly shown) the gate stack (e.g., gate dielectric layer 428 and gate electrode 430). Implant mask 453 is then removed.

Next, FIG. 4L illustrates formation of sidewall spacer structures 432 along the lateral sides of the gate electrode 430. The sidewall spacer structures 432, in the FIG. 4L example, include an oxide layer 434 and a nitride layer 436 which may be formed the same or similar to the sidewall spacer structures in semiconductor device 200. Although not explicitly illustrated in FIG. 4L, prior to forming the sidewall spacer structures 432, one or more implant processes can be done to introduce n-type dopants in the DPWELL 414—e.g., under the sidewall spacer structures 432. The n-type region formed as a result of the one or more implant processes extends along the top side of the p-type DPWELL 414 and provides electrical connection between the channel under the gate stack and a later formed n-type source region (e.g., source region 410).

In a next intermediate stage, as shown in FIG. 4M, the symmetric field relief layer 421 is etched using a second mask layer 425 to form an opening 449 exposing the N-DRIFT region 420. The opening 449 as will be described below, corresponds to an area where a drain region (e.g., a drain region 418 shown in FIG. 4O) will be formed. As a result, the symmetric field relief layer 421 is modified (divided) forming an asymmetric field relief layer 422 to the right of the opening 449 and a residual dielectric material 423 to the left of the opening 449. In some examples, residual dielectric material 423 can be removed or, alternatively, can remain to provide isolation from an adjacent device (not expressly shown). In some examples, opening 449 has a width in the X direction of about 100 to 200 nm (e.g., 150 nm). In some examples, if any of the silicon of the exposed N-DRIFT region 420 is damaged during the etch process, the damage may be annealed or otherwise mitigated by the subsequent formation of the drain region. The second mask layer 425 is then removed.

As shown in FIG. 4N, the asymmetric field relief layer 422 includes a first end 424 with a first profile and a second end 426 with a second profile. While the second end 426 has a bird's beak (tapered) profile (originally formed as part of the symmetric field relief layer 421), the first end 424 now has a profile substantially perpendicular to the top surface 427 of the semiconductor layer 408 (since the substantially symmetric bird's beak profile originally formed as part of the symmetric field relief layer 421 is now detached or otherwise removed—e.g., residual dielectric material 423-after formation of the asymmetric field relief layer 422). In some examples, the term “substantially perpendicular” may be defined as the first profile of the first end 424 having an angle A₁ of 90+/−20 degrees relative to the direction along the top surface 427 of the semiconductor layer 408. Also, the first profile of the first end 424 of the asymmetric field relief layer 422 has a slope greater than (and a width narrower than) the second profile of the second end 426 of the asymmetric field relief layer 422.

In FIG. 4O, a source region 410 and a drain region 418 are formed in the semiconductor layer 408 with an n-type dopant(s). More particularly, an implantation process 429 is performed with an implant mask 431 to implant the source region 410 in the DPWELL 414 and the drain region 418 in the N-DRIFT region 420 (the latter utilizing the opening 449 of FIG. 4M). In some examples, the source/drain implant is relatively shallow and may not penetrate the asymmetric field relief layer 422 and/or the gate stack (e.g., gate dielectric layer 428 and gate electrode 430). In some examples using an angled implant, or otherwise due to diffusion, source region 410—while remaining within the DPWELL 414—can underlap (not expressly shown) the gate stack (e.g., gate dielectric layer 428 and gate electrode 430).

In some examples, as shown in the FIG. 4O example, the drain region 418 is recessed in the Z direction relative to the source region 410. For example, in some examples, a top surface 461 of the drain region 418 is recessed at a depth D₁ in the Z direction relative to a top surface 471 of the source region 410. Further, in some examples, a bottom surface 463 of the drain region 418 is recessed at a depth D₂ in the Z direction relative to a bottom surface 473 of the source region 410. Still further, in some examples, the top surface 461 of the drain region 418 is recessed at a depth D₃ (e.g., substantially equal to D₁) relative to the top surface 427 of the semiconductor layer 408, while the top surface 471 of the source region 410 is coplanar or substantially coplanar with the top surface 427 of the semiconductor layer 408.

FIG. 4P illustrates formation of a body contact region 412 in the semiconductor layer 408 with a p-type dopant(s). More particularly, an implantation process 465 is performed with an implant mask 467 to implant the body contact region 412 in the DPWELL 414 adjacent the source region 410.

Next, FIG. 4Q illustrates formation of a metal silicide layers 438 that respectively extend over the source region 410, the body contact region 412, the drain region 418, and the gate electrode 430. In some examples, a metal silicide process includes depositing a metal layer (not expressly shown), for example, using a blanket deposition process. In some examples, a silicide-blocking layer may be formed prior to depositing the metal layer to define areas exposed to the blanket deposition process. The semiconductor device 400 is then heated to form the metal silicide layers 438 over the intended areas (e.g., the source region 410, the body contact region 412, the drain region 418, and the gate electrode 430) and unreacted metal is subsequently removed in a wet stripping process.

Lastly, FIG. 4R shows formation of a nitride etch stop layer 440 that extends over portions of the metal silicide layers 438 and the sidewall spacer structures 432, as well as a pre-metal dielectric (PMD) layer 442, conductive metal (e.g., tungsten) contacts 444 and 446 for a source region 410 and the drain region 418, and a conductive metal contact (not expressly shown) for the gate electrode 430. Still further, as shown, metal interconnects 448 and 450 are formed and conductively coupled to the respective source and drain contacts (conductive metal contacts 444 and 446).

Following the process flow of FIGS. 4A-4R, the finished wafer can then be separated (e.g., die singulation) to separate individual semiconductor dies from the starting wafer, and the dies can then be packaged to form integrated circuits or other packaged semiconductor devices.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A semiconductor device, comprising:
a semiconductor layer;
a drain region disposed in the semiconductor layer;
a source region disposed in the semiconductor layer;
a gate stack disposed between the drain region and the source region; and
an asymmetric field relief layer disposed at least partially in the semiconductor layer between the drain region and the source region, the asymmetric field relief layer having a first end with a first profile and a second end with a second profile different than the first profile.

2. The semiconductor device of claim 1, wherein the first end of the asymmetric field relief layer is adjacent to the drain region and the second end of the asymmetric field relief layer is adjacent to the source region.

3. The semiconductor device of claim 1, wherein the asymmetric field relief layer includes an oxide layer.

4. The semiconductor device of claim 1, wherein the first end with the first profile includes a first tapered portion having a first slope, and the second end with the second profile includes a second tapered portion having a second slope less than the first slope.

5. The semiconductor device of claim 1, wherein the first end with the first profile includes a first tapered portion having a first width extending in a direction along a surface of the semiconductor layer, and the second end with the second profile includes a second tapered portion having a second width extending in the direction along the surface of the semiconductor layer and greater than the first width.

6. The semiconductor device of claim 1, wherein the first profile includes a first bird's beak profile and the second profile includes a second bird's beak profile different than the first bird's beak profile.

7. The semiconductor device of claim 1, wherein the first profile includes a profile substantially perpendicular to a surface of the semiconductor layer and the second profile includes a bird's beak profile.

8. The semiconductor device of claim 1, wherein a surface of the drain region is recessed with respect to a surface of the source region.

9. A semiconductor device, comprising:
a semiconductor layer;
a drain region disposed in the semiconductor layer;
a source region disposed in the semiconductor layer;
a gate stack disposed between the drain region and the source region; and
a field relief layer disposed between the drain region and the source region, and at least partially in the semiconductor layer, the field relief layer having a first end adjacent to the drain region with a first profile and a second end adjacent to the source region with a second profile, wherein the first profile is smaller in width, defined in a direction along a surface of the semiconductor layer, relative to the second profile.

10. The semiconductor device of claim 9, wherein the first profile includes a first bird's beak profile and the second profile includes a second bird's beak profile different than the first bird's beak profile.

11. The semiconductor device of claim 9, wherein the first end with the first profile includes a first tapered portion having a first slope, and the second end with the second profile includes a second tapered portion having a second slope less than the first slope.

12. The semiconductor device of claim 9, wherein the field relief layer includes an oxide layer.

13. A semiconductor device, comprising:
a semiconductor layer;
a drain region disposed in the semiconductor layer;
a source region disposed in the semiconductor layer;
a gate stack disposed between the drain region and the source region; and
a field relief layer disposed between the drain region and the source region, and at least partially in the semiconductor layer, the field relief layer having a first end adjacent to the drain region with a first profile and a second end adjacent to the source region with a second profile, wherein the first profile includes a profile substantially perpendicular to a direction along a surface of the semiconductor layer and the second profile includes a tapered portion.

14. The semiconductor device of claim 13, wherein the first profile is defined relative to an edge of the drain region and the second profile includes a bird's beak profile.

15. The semiconductor device of claim 13, wherein a surface of the drain region is recessed with respect to a surface of the source region.

16. The semiconductor device of claim 13, wherein substantially perpendicular includes the first profile being 90+/−20 degrees relative to the direction along the surface of the semiconductor layer.

17. A method of fabricating a semiconductor device, comprising:
forming an asymmetric field relief layer disposed partially in a semiconductor layer and partially above a surface of the semiconductor layer, the asymmetric field relief layer having a first end with a first profile and a second end with a second profile different than the first profile; and
forming a drain region, a source region, and a gate stack, the drain region being proximate to the first end of the asymmetric field relief layer, the source region being proximate to the second end of the asymmetric field relief layer, and the gate stack being between the drain region and the source region and partially over the asymmetric field relief layer.

18. The method of claim 17, wherein forming the asymmetric field relief layer further comprises:
forming an oxide-based layer on the surface of the semiconductor layer; and
forming a nitride-based layer on the oxide-based layer.

19. The method of claim 18, wherein forming the asymmetric field relief layer further comprises:
etching the nitride-based layer using a first mask that defines a field relief opening.

20. The method of claim 19, wherein forming the asymmetric field relief layer further comprises:
further etching the nitride-based layer using a second mask to form a first portion of the nitride-based layer on one side of the field relief opening and a second portion of the nitride-based layer on another side of the field relief opening, the first portion being thicker than the second portion.

21. The method of claim 20, wherein forming the asymmetric field relief layer further comprises:
thermally growing an oxide layer in the field relief opening to form the asymmetric field relief layer.

22. The method of claim 19, wherein forming the asymmetric field relief layer further comprises:
thermally growing an oxide layer in the field relief opening.

23. The method of claim 22, wherein forming the asymmetric field relief layer further comprises:
removing the nitride-based layer.

24. The method of claim 23, wherein forming the asymmetric field relief layer further comprises:
etching the oxide layer using a second mask that defines an opening corresponding to the drain region.

25. The method of claim 24, wherein the opening in the oxide layer is used to form the drain region adjacent to the first end of the asymmetric field relief layer.

26. The method of claim 17, wherein the drain region is formed such that a surface of the drain region is recessed with respect to a surface of the source region.

27. The method of claim 19, wherein the first profile of the first end of the asymmetric field relief layer is defined before forming an oxide layer in the field relief opening.

28. The method of claim 19, wherein the first profile of the first end of the asymmetric field relief layer is defined after forming an oxide layer in the field relief opening.
